(19) United States
(12) Patent Application Publication
(10) Pub. No.: US 2007/0144259 A1
(43) Pub. Date: Jun. 28, 2007

(54) Semiconductor acceleration sensor and fabrication method thereof

(76) Inventor: Yoshihiko Ino, Miyazaki (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/605,366

(22) Filed: Nov. 29, 2006

(30) Foreign Application Priority Data
Dec. 1, 2005 (JP) 2005-347466

(51) Int. Cl. G01P 15/12; H01L 21/28

(52) U.S. Cl. 73/514.33; 438/51

(57) ABSTRACT

A semiconductor acceleration sensor chip has a fixed portion having a first thickness, a weight portion surrounding the fixed portion from a periphery, a beam portion having the first thickness and connecting the fixed portion and the weight portion such that the weight portion can displace with respect to the fixed portion, and a piezo element formed at the beam portion. The fixed portion is fastened to a lower container having a pedestal portion which projects-out at a center of a bottom surface of a cavity. In accordance with the above-described structure, there are provided a semiconductor acceleration sensor and method of manufacture thereof which can realize simplification of manufacturing processes and prevention of a decrease in yield, without a sensor sensitivity decreasing.

### CROSS-REFERENCE TO RELATED APPLICATION

This application claims priority under 35 USC 119 from Japanese Patent Application No. 2005-347466, the disclosure of which is incorporated by reference herein.

### BACKGROUND OF THE INVENTION

1. Field of the Invention

The present invention relates to a semiconductor acceleration sensor and a method of manufacture thereof, and in particular, to a semiconductor acceleration sensor which can detect acceleration in each of three dimensions, and a method of manufacture thereof.

2. Description of the Related Art

In recent years, acceleration sensors have been widely used in various industrial fields such as automobiles, robots, various types of precision machines, and the like. Among these, the demand for semiconductor acceleration sensors which use MEMS (Micro Electro Mechanical System) technology has rapidly increased from the standpoints that they are compact and light-weight, precise and reliable operation can be expected thereof, they are low-cost, and the like.

Among semiconductor acceleration sensors, there are those which carry out sensing of acceleration by utilizing the piezoresistance effect, i.e., the phenomenon that the resistance value varies proportionately to the generated stress. Such a semiconductor acceleration sensor generally has a structure in which a semiconductor chip (hereinafter called a sensor chip) which forms a sensor portion is accommodated at the interior of a package which is formed of a ceramic.

A sensor chip utilizing the piezoresistance effect has a weight portion disposed at the center, four beam portions which are flexible, and a substantially square fixed portion to which one end of each of the four beam portions is fixed. The weight portion has a structure in which it is supported by the four beam portions from four sides. A piezoresistance element is affixed to each beam portion, and a Wheatstone bridge circuit is structured due to these being connected by a wiring pattern.

When a change in velocity arises at a semiconductor acceleration sensor having such a sensor chip, the beam portions flex due to the stress generated by the inertial movement of the weight portion. Simultaneously, the piezoresistance elements affixed to the beam portions flex as well. Because the resistance value of each piezoresistance element changes due to this flexing, the resistance balance of the Wheatstone bridge varies. The acceleration can be sensed due to this change in the resistance balance being measured as a change in current or a change in voltage.

A semiconductor acceleration sensor such as described above is disclosed in Japanese Patent Application Publication (JP-B) No. 8-7228 for example.

However, in the semiconductor acceleration sensor in accordance with the conventional art, in order to improve the sensor sensitivity, the beam portions must be formed to be thinner than the weight portion and the fixed portion. Therefore, there is the problem that the manufacturing process is complex. Further, at the time of machining the beam portion to be thin, there is also the possibility that it may break, and the problem exists that there is also the possibility that the yield may decrease.

Thus, the present invention was made in consideration of the above-described problems, and an object thereof is to provide a semiconductor acceleration sensor and a method of manufacture thereof which can realize simplification of the manufacturing process and prevention of a decrease in yield, without the sensor sensitivity decreasing.

### SUMMARY OF THE INVENTION

In order to achieve this object, a semiconductor acceleration sensor in accordance with the present invention is structured to have: a fixed portion having a first thickness; a weight portion surrounding the fixed portion from a periphery; a beam portion having the first thickness, and connecting the fixed portion and the weight portion such that the weight portion can displace with respect to the fixed portion; and a piezo element formed at the beam portion.

By making the thickness of the fixed portion, which is fastened to the package at the time of accommodating the semiconductor acceleration sensor in a predetermined package, and the thickness of the beam portion, be the same first thickness, a process for making the beam portion thinner than the fixed portion becomes unnecessary, and therefore, the manufacturing method can be simplified. Further, by simplifying the manufacturing method, breakage at the time of manufacturing can be prevented. In this way, the yield of the semiconductor acceleration sensor can be improved. Note that, because the beam portion can be made thin to the needed thickness, the sensor sensitivity of the semiconductor acceleration sensor is not lowered.

Further, a method of manufacturing a semiconductor acceleration sensor in accordance with the present invention is structured to have: a step of readying a semiconductor acceleration substrate having a first electrode pad formed at a first region at a top surface, a piezo element formed at a second region which is at a periphery of the first region at the top surface, and a wiring pattern electrically connecting the first electrode pad and the piezo element; a step of excavating, from a reverse surface, the first region and the second region at the semiconductor substrate, such that a first thickness remains; and a step of individuating the semiconductor substrate at an end of a third region which surrounds the second region.

In a case in which the first region is made to be the fixed portion which is fastened to the package, and the third region is made to be the weight portion, and the second region is made to be the beam portion which connects the fixed portion and the weight portion, by making the thickness of the first region and the thickness of the second region be the same first thickness, a process for making the beam portion thinner than the fixed portion becomes unnecessary, and therefore, the manufacturing method can be simplified. Further, by simplifying the manufacturing method, breakage at the time of manufacturing can be prevented. In this way, the yield of the semiconductor acceleration sensor can be improved. Note that, because the second region can be made thin to the needed thickness, the sensor sensitivity of the semiconductor acceleration sensor is not lowered.

Moreover, a method of manufacturing a semiconductor acceleration sensor in accordance with the present invention is structured to have: a step of readying a semiconductor acceleration substrate having a first electrode pad formed at a first region at a top surface, a piezo element formed at a second region which is at a periphery of the first region at the top surface, and a wiring pattern electrically connecting the first electrode pad and the piezo element; a step of excavating, from a reverse surface, the first region and the second region and a third region which is at a periphery of the second region at the semiconductor substrate, such that a first thickness remains; and a step of individuating the semiconductor substrate at an end of a fourth region which is at a periphery of the third region.

In a case in which the first region is made to be the fixed portion which is fastened to the package, and the third and fourth regions are made to be the weight portion, and the second region is made to be the beam portion which connects the fixed portion and the weight portion, by making the thickness of the first region and the thickness of the second region be the same first thickness, a process for making the beam portion thinner than the fixed portion becomes unnecessary, and therefore, the manufacturing method can be simplified. Further, by simplifying the manufacturing method, breakage at the time of manufacturing can be prevented. In this way, the yield of the semiconductor acceleration sensor can be improved. Note that, because the second region can be made thin to the needed thickness, the sensor sensitivity of the semiconductor acceleration sensor is not lowered. Moreover, by making the thickness of the third region which is the inner peripheral portion of the weight portion, and the thicknesses of the first region which is the fixed portion and the second region which is the beam portion, be the same first thickness, the stress at the time when the weight portion displaces with respect to the fixed portion can be prevented from concentrating at the connected portion of the beam portion and the weight portion, i.e., at the root portion of the second region and the third region. As a result, the shock-resistance of the semiconductor acceleration sensor can be improved.

In accordance with the present invention, a semiconductor acceleration sensor and method of manufacture thereof, which can realize simplification of manufacturing processes and prevention of a decrease in yield without the sensor sensitivity decreasing, can be realized.

### BRIEF DESCRIPTION OF THE DRAWINGS

Preferred exemplary embodiments of the present invention will be described in detail based on the following figures, wherein:

FIG. 1A is a perspective view showing the schematic structure when viewing; obliquely from above, a semiconductor acceleration sensor chip 10 in accordance with example 1 of the present invention;

FIG. 1B is a perspective view showing the schematic structure when viewing, obliquely from below, the semiconductor acceleration sensor chip 10 in accordance with example 1 of the present invention;

FIG. 2A is a top view of the semiconductor acceleration sensor chip 10 in accordance with example 1 of the present invention;

FIG. 2B is an A-A sectional view in FIG. 2A;

FIG. 2C is a bottom view of the semiconductor acceleration sensor chip 10 in accordance with example 1 of the present invention;

FIG. 3A is a top view showing the structure of a semiconductor acceleration sensor device 100 in accordance with example 1 of the present invention;

FIG. 3B is a B-B sectional view in FIG. 3A;

FIG. 4A is a process diagram showing a method of manufacturing the semiconductor acceleration sensor chip 10 in accordance with example 1 of the present invention;

FIG. 4B is a process diagram showing the method of manufacturing the semiconductor acceleration sensor chip 10 in accordance with example 1 of the present invention;

FIG. 4C is a process diagram showing the method of manufacturing the semiconductor acceleration sensor chip 10 in accordance with example 1 of the present invention;

FIG. 4D is a process diagram showing the method of manufacturing the semiconductor acceleration sensor chip 10 in accordance with example 1 of the present invention;

FIG. 5A is a process diagram showing a method of manufacturing the semiconductor acceleration sensor device 100 in accordance with example 1 of the present invention;

FIG. 5B is a process diagram showing the method of manufacturing the semiconductor acceleration sensor device 100 in accordance with example 1 of the present invention;

FIG. 5C is a process diagram showing the method of manufacturing the semiconductor acceleration sensor device 100 in accordance with example 1 of the present invention;

FIG. 5D is a process diagram showing the method of manufacturing the semiconductor acceleration sensor device 100 in accordance with example 1 of the present invention;

FIG. 5E is a process diagram showing the method of manufacturing the semiconductor acceleration sensor device 100 in accordance with example 1 of the present invention;

FIG. 5F is a process diagram showing the method of manufacturing the semiconductor acceleration sensor device 100 in accordance with example 1 of the present invention;

FIG. 5G is a process diagram showing the method of manufacturing the semiconductor acceleration sensor device 100 in accordance with example 1 of the present invention;

FIG. 6A is a perspective view showing the schematic structure when viewing, obliquely from above, a semiconductor acceleration sensor chip 20 in accordance with example 2 of the present invention;

FIG. 6B is a perspective view showing the schematic structure when viewing, obliquely from below, the semiconductor acceleration sensor chip 20 in accordance with example 2 of the present invention;

FIG. 7A is a top view of the semiconductor acceleration sensor chip 20 in accordance with example 2 of the present invention;

FIG. 7B is a C-C sectional view in FIG. 7A;

FIG. 7C is a bottom view of the semiconductor acceleration sensor chip 20 in accordance with example 2 of the present invention;

FIG. 8A is a top view showing the structure of a semiconductor acceleration sensor device 200 in accordance with example 2 of the present invention;

FIG. 8B is a D-D sectional view in FIG. 8A;

FIG. 9A is a top view of a semiconductor acceleration sensor chip 30 in accordance with example 3 of the present invention;

FIG. 9B is an E-E sectional view in FIG. 9A;

FIG. 9C is an F-F sectional view in FIG. 9A;

FIG. 10 is a bottom view of the semiconductor acceleration sensor chip 30 in accordance with example 3 of the present invention;

FIG. 11A is a top view showing the structure of a semiconductor acceleration sensor device 300 in accordance with example 3 of the present invention;

FIG. 11B is a G-G sectional view in FIG. 11A;

FIG. 12A is a process diagram showing a method of manufacturing the semiconductor acceleration sensor device 300 in accordance with example 3 of the present invention;

FIG. 12B is a process diagram showing the method of manufacturing the semiconductor acceleration sensor device 300 in accordance with example 3 of the present invention;

FIG. 12C is a process diagram showing the method of manufacturing the semiconductor acceleration sensor device 300 in accordance with example 3 of the present invention;

FIG. 13A is a top view of a semiconductor acceleration sensor chip 40 in accordance with example 4 of the present invention;

FIG. 13B is an H-H sectional view in FIG. 13A;

FIG. 13C is an I-I sectional view in FIG. 13A;

FIG. 14 is a bottom view of the semiconductor acceleration sensor chip 40 in accordance with example 4 of the present invention;

FIG. 15A is a top view showing the structure of a semiconductor acceleration sensor device 400 in accordance with example 4 of the present invention;

FIG. 15B is a J-J sectional view in FIG. 15A;

FIG. 16 is a top view of a semiconductor acceleration sensor device 500 in accordance with example 5 of the present invention;

FIG. 17A is a K-K sectional view in FIG. 16;

FIG. 17B is an L-L sectional view in FIG. 16;

FIG. 18A is a process diagram showing a method of manufacturing the semiconductor acceleration sensor device 500 in accordance with example 5 of the present invention;

FIG. 18B is a process diagram showing the method of manufacturing the semiconductor acceleration sensor device 500 in accordance with example 5 of the present invention;

FIG. 18C is a process diagram showing the method of manufacturing the semiconductor acceleration sensor device 500 in accordance with example 5 of the present invention;

FIG. 18D is a process diagram showing the method of manufacturing the semiconductor acceleration sensor device 500 in accordance with example 5 of the present invention;

FIG. 18E is a process diagram showing the method of manufacturing the semiconductor acceleration sensor device 500 in accordance with example 5 of the present invention;

FIG. 18F is a process diagram showing the method of manufacturing the semiconductor acceleration sensor device 500 in accordance with example 5 of the present invention;

FIG. 18G is a process diagram showing the method of manufacturing the semiconductor acceleration sensor device 500 in accordance with example 5 of the present invention; and

FIG. 18H is a process diagram showing the method of manufacturing the semiconductor acceleration sensor device 500 in accordance with example 5 of the present invention.

### DETAILED DESCRIPTION OF THE INVENTION

Hereinafter, preferred embodiments for implementing the present invention will be described in detail together with the drawings. Note that, in the following description, the drawings merely schematically illustrate configurations, sizes and positional relationships to the extent that the contents of the present invention can be understood, and accordingly, the present invention is not limited only to the configurations, sizes and positional relationships exemplified in the respective drawings. Further, in order to clarify the structures in the respective drawings, a portion of the hatching in cross-section is omitted. Moreover, the exemplary numerical values in the following description are merely suitable examples of the present invention, and accordingly, the present invention is not limited to the exemplary numerical values.

### Example 1

First, a semiconductor acceleration sensor device 100 in accordance with example 1 of the present invention will be described in detail by using the drawings.

<Structure of Semiconductor Acceleration Sensor Chip 10>

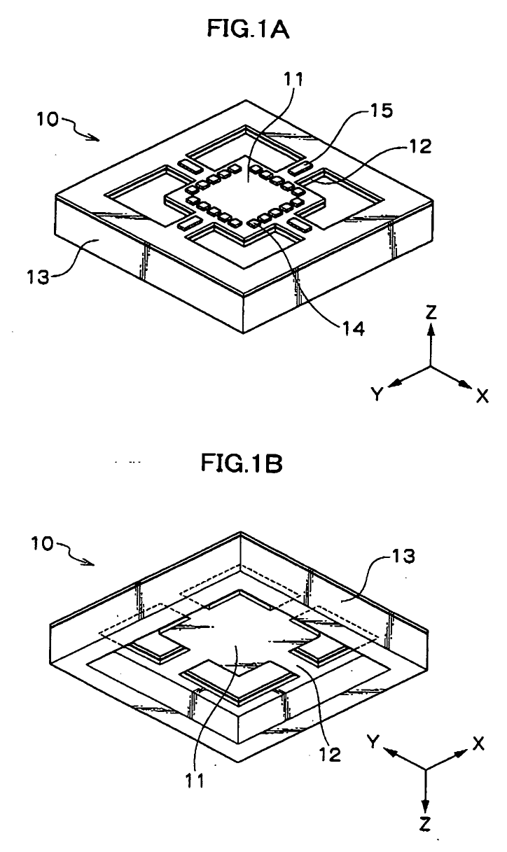

FIG. 1A is a perspective view showing the schematic structure when viewing, obliquely from above, a semiconductor acceleration sensor chip 10 which is a three-dimensional acceleration sensor in accordance with the present example. FIG. 1B is a perspective view showing the schematic structure when viewing, obliquely from below, the semiconductor acceleration sensor chip 10. Note that, in the present example, description is given by using, as an example, a three-dimensional acceleration sensor which utilizes the piezoresistance effect, i.e., the phenomenon that the resistance value varies in proportion to the generated stress.

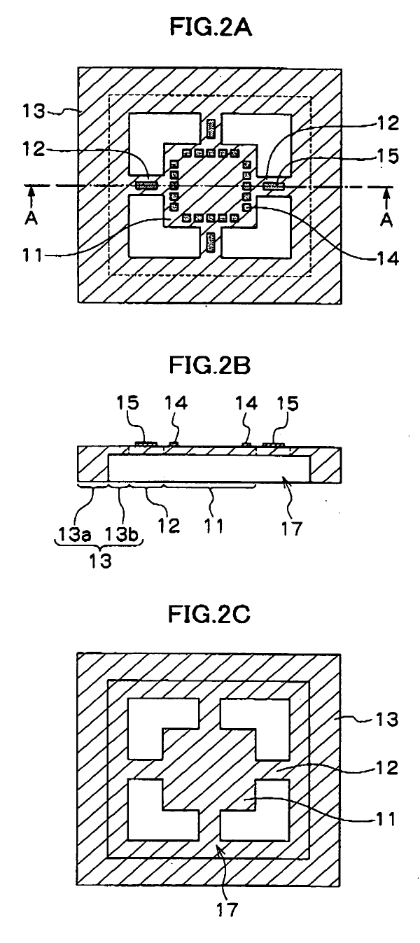

Further, FIG. 2A is a top view of the semiconductor acceleration sensor chip 10, FIG. 2B is an A-A sectional view in FIG. 2A, and FIG. 2C is a bottom view of the semiconductor acceleration sensor chip 10.

As shown in FIG. 1 and FIG. 2, the semiconductor acceleration sensor chip 10 has a fixed portion 11 and beam portions 12 and a weight portion 13 and electrode pads 14 and piezo elements 15. The fixed portion 11 and the beam portions 12 and the weight portion 13 are formed integrally by machining a predetermined semiconductor substrate. Note that a silicon substrate or the like, for example, can be applied as the predetermined semiconductor substrate at which the fixed portion 11 and the beam portions 12 and the weight portion 13 are built-in.

The semiconductor substrate formed from the fixed portion 11, the beam portions 12, and the weight portion 13 is a quadrilateral-columnar member which has, at the interior thereof, a cavity 17 whose opening configuration is square, and at which the top surface side of the cavity 17 is closed. In other words, the semiconductor substrate which structures the semiconductor acceleration sensor chip 10 has the cavity 17 which is formed by opening from the reverse surface side. Due to this structure, the fixed portion 11 and the beam portions 12 and an inner peripheral portion 13b of the weight portion 13 are made to be thinner-walled than an outer peripheral portion 13a of the weight portion 13.

In the above-described structure, the configuration of the fixed portion 11 when viewed from above is a square for example, and the fixed portion 11 is disposed at the center of the acceleration sensor chip 10 (see FIG. 2).

The configuration of the weight portion 13 when viewed from above is, for example, a square having at the center thereof a square opening which is a size larger than the fixed portion 11. The weight portion 13 is disposed so as to surround the fixed portion 11 from the four sides (see FIG. 1 and FIG. 2). In other words, the weight portion 13 is a ring-shaped member assuming the shape of a square edge for example, and has a quadrilateral opening portion at the central portion thereof.

Four, for example, of the beam portions 12 are provided, and connect the substantial centers of the sides at the inner side of the weight portion 13 and the substantial centers of the sides of the fixed portion 11 respectively (see FIG. 1 and FIG. 2). Each beam portion 12 is formed so as to flex due to the inertial movement of the weight portion 13 when acceleration is applied to the semiconductor acceleration sensor chip 10. Namely, the beam portions 12 are flexible. In this way, the weight portion 13 and the fixed portion 11 are connected by the four beam portions 12 such that the weight portion 13 can displace with respect to the fixed portion 11.

In the present example, in order for the beam portions 12 to be structured so as to flex with respect to the inertial movement of the weight portion 13, the thickness of the beam portions 12 is made to be about 0.01 mm for example, and the thickness of the thickest portion of the weight portion 13 is made to be about 0.4 mm for example. Further, the width of the top surface of the beam portion 12 is made to be about 0.1 mm for example, and the length thereof is made to be about 0.3 mm for example.

Further, in the present example, the thickness of the fixed portion 11 is made to be the same as the thickness of the beam portions 12 (see FIG. 2B). In this way, a process for machining the beam portions 12 to be thinner than the fixed portion 11 is not needed, and the manufacturing process is simplified, and breakage at the time of manufacturing is prevented such that the yield improves. Moreover, due to this structure, the stress at the time when the weight portion 13 displaces with respect to the fixed portion 11 can be prevented from concentrating at the connected portions of the beam portions 12 and the fixed portion 11, i.e., at the root portions of the beam portions 12. As a result, the shock-resistance of the semiconductor acceleration sensor chip 10 improves. The thickness of the fixed portion 11 is made to be, in the same way as the aforementioned thickness of the beam portions 12, about 0.01 mm for example.

Further, in the present example, the inner side of the weight portion 13, i.e., the portion at the side which is open (see 13b in FIG. 2B), is machined to the same thinness as the beam portions 12. In other words, the inner peripheral portion 13b of the weight portion 13 has the same thickness as the beam portions 12. In this way, the stress at the time when the weight portion 13 displaces with respect to the fixed portion 11 can be prevented from concentrating at the connected portions of the beam portions 12 and the weight portion 13, i.e., at the root portions of the beam portions 12. As a result, the shock-resistance of the semiconductor acceleration sensor chip 10 can be improved. The thickness of the inner peripheral portion 13b can be made to be, in the same way as the aforementioned thickness of the beam portions 12, about 0.01 mm for example. Further, the thickness of the portion other than the inner peripheral portion 13b, i.e., the outer peripheral portion 13a (see FIG. 2B), is about 0.4 mm for example, as described above. Moreover, at the weight portion 13, the width of the inner peripheral portion 13b, i.e., the width from the inner side to the outer side, can be made to be about 0.1 mm for example, and the width of the outer peripheral portion 13a can be made to be about 0.3 mm for example.

In addition, the length of one side of the fixed portion 11 when viewed from above can be made to be about 0.8 mm for example.

Further, the piezo elements 15 are formed on the top surfaces of the respective beam portions 12. Moreover, the electrode pads 14 are formed on the top surface of the fixed portion 11. A Wheatstone bridge circuit is structured by the piezo elements 15 and the electrode pads 14 being electrically connected by an unillustrated wiring pattern. By sensing the resistance balance of the piezo elements 15 via the electrode pads 14 and the unillustrated wiring pattern, the amounts of flexure arising at the beam portions 12 can be detected, and further, the magnitude and the direction of the acceleration applied to the semiconductor acceleration sensor chip 10 can be specified from these amounts of flexure.

Moreover, in the semiconductor acceleration sensor chip 10 having a structure such as described above, the fixed portion 11 is fastened to a pole-shaped pedestal portion 101c which is provided at a bottom plate 101b of a lower container 101 which will be described later. By forming a structure in which the fixed portion 11, which is disposed at the center of the weight portion 13, is fixed to the pole-shaped pedestal portion 101c in this way, the effects which the semiconductor acceleration sensor chip 10 receives at the time when a package, which is formed from the lower container 101 which will be described later and an upper cover 111, deforms can be reduced. Therefore, the need to reinforce the mechanical strength of the semiconductor acceleration sensor chip 10 by using, for example, a glass substrate or the like, is eliminated, and as a result, the manufacturing process can be simplified.

<Structure of Semiconductor Acceleration Sensor Device 100>

Next, the structure of the semiconductor acceleration sensor device 100 in accordance with the present example, which is formed by the above-described semiconductor acceleration sensor chip 10 being accommodated in a package formed from the lower container 101 which will be described later and the upper cover 111, will be described in detail together with the drawings.

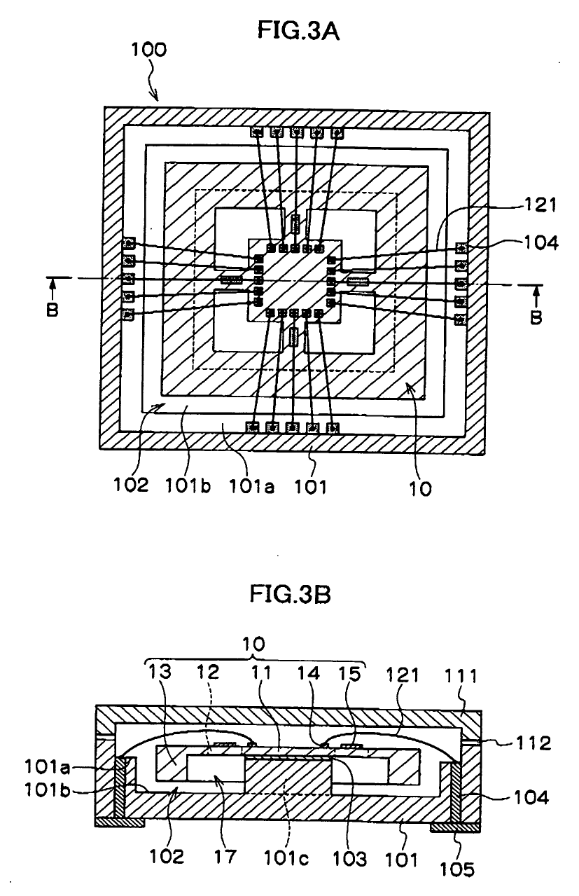

FIG. 3A is a top view showing the structure of the semiconductor acceleration sensor device 100. Further, FIG. 3B is a B-B sectional view in FIG. 3A. Note that, for convenience of explanation, the structures of a thermosetting resin 112 and the upper cover 111 at the semiconductor acceleration sensor device 100 are omitted in FIG. 3A.

As shown in FIG. 3A and FIG. 3B, the semiconductor acceleration sensor device 100 has the lower container 101 which accommodates the semiconductor acceleration sensor chip 10, and the upper cover 111 which seals the lower container 101.

The lower container 101 is, for example, a package which is made of ceramic and has a layered structure. The lower container 101 has a cavity 102 for accommodating the semiconductor acceleration sensor chip 10.

The cavity 102 is a size larger than the outer dimension of the semiconductor acceleration sensor chip 10. Accordingly, the semiconductor acceleration sensor chip 10 is accommodated within the cavity 102 such that the weight portion 13 is in a midair state.

The side wall of the lower container 101, which forms the side surface of the cavity 102, has a structure in which the inner side thereof, i.e., the cavity 102 side thereof, is a step lower than the top surface at the outer side. The top surface which is a step lower than this outer side top surface is called a lower step surface 101a. The upper ends of via wires 104, which are formed so as to pass through the interior of the side wall to the bottom surface of the lower container 101, are exposed at the lower step surface 101a. Other ends of wires 121, whose one ends are attached to the electrode pads 14 of the semiconductor acceleration sensor chip 10, are attached to these exposed portions. Further, the lower ends of the via wires 104 exposed at the bottom surface of the lower container 101 are electrically connected to electrode pads (these are called a foot pattern 105) formed on the bottom surface of the lower container 101. In this way, the electrode pads 14 of the semiconductor acceleration sensor chip 10 are electrically lead-out to the foot pattern 105 of the bottom surface of the lower container 101, via the wires 121 and the via wires 104. This foot pattern 105 is electrode pads which are electrically connected to electrode pads at an unillustrated circuit substrate or the like.

As described above, the pole-shaped pedestal portion 101c, which projects-out into the cavity 102, is provided at the bottom plate 101b of the lower container 101. The configuration of the pedestal portion 101c when viewed from above is, for example, a square which is a size smaller than the fixed portion 11. However, the pedestal portion 101c is not limited to the same, and may be modified in any way provided that it is of a size and a configuration which does not protrude-out from the fixed portion 11 of the semiconductor acceleration sensor chip 10 when viewed from above, and is of an extent that it can fasten the fixed portion 11 with sufficient strength. As described above, the bottom surface of the fixed portion 11 of the semiconductor acceleration sensor chip 10 is fastened to the top surface of the pedestal portion 101c. Accordingly, the upper portion of the pedestal portion 101c is accommodated in the cavity 17 of the semiconductor acceleration sensor chip 10. For the fastening of the fixed portion 11 and the pedestal portion 101c, a resin 103 of a polyorganosiloxane or the like having a siloxane bond (Si—O) as the skeleton, such as a silicone resin or the like for example, can be used. Further, other than this, for example, a fluorine resin or the like can be applied.

As described above, ones of ends of the wires 121 are attached to the via wires 104 which are exposed at the lower step surface 101a of the side wall of the lower container 101. Further, also as described above, the other ends of the wires 121 are attached to the electrode pads 14 of the semiconductor acceleration sensor chip 10. Metal wires of, for example, gold or copper or aluminum or the like, can be used as these wires 121. Further, the wires 121 can be bonded to the via wires 104 and the electrode pads 14 by using, for example, ultrasonic and thermocompression bonding or the like.

Moreover, the open side of the lower container 101, in which the semiconductor acceleration sensor chip 10 is accommodated within the cavity 102 as described above, is sealed by the upper cover 111. For example, 42 Alloy alloy or stainless or the like can be used as the material of the upper cover 111. The thermosetting resin 112, such as an epoxy resin or the like, can be used in the adhering of the lower container 101 and the upper cover 111. Note that the interior of the package formed from the lower container 101 and the upper cover 111 is purged by, for example, nitrogen gas or dry air or the like.

<Method of Manufacturing Semiconductor Acceleration Sensor Chip 10>

Next, a method of manufacturing the semiconductor acceleration sensor chip 10 in accordance with the present example will be described in detail together with the drawings.

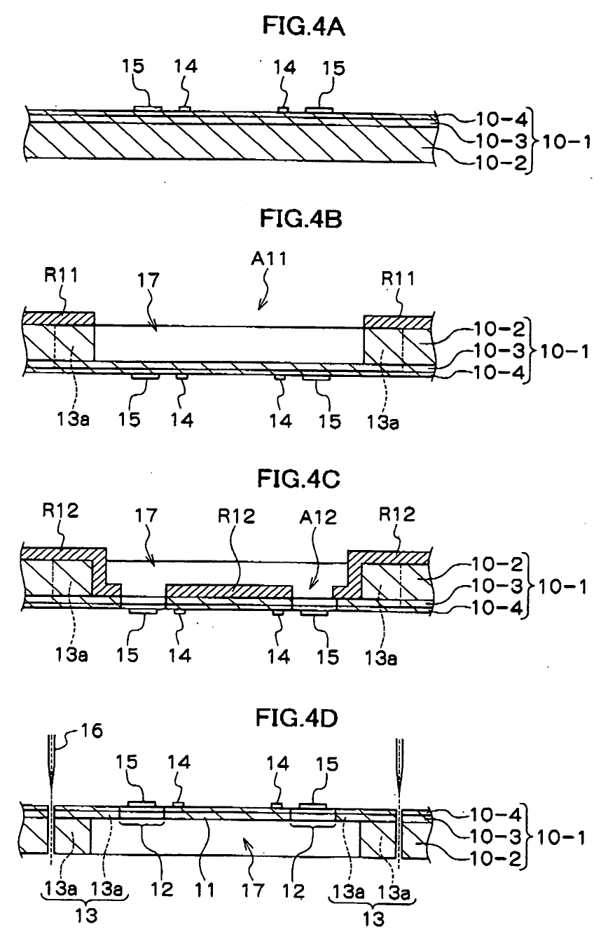

In the present example, first, as shown in FIG. 4A, an SOI (Silicon On Insulator) substrate 10-1, at which the piezo elements 15, the electrode pads 14, and a wiring pattern (not shown) electrically connecting these are formed, is readied. Note that the SOI substrate 10-1 has a silicon substrate 10-2 which is a buckle substrate for example, a buried oxide film (BOX: Buried Oxide) which is a silicon oxide film formed on the silicon substrate 10-2, and a silicon thin film 10-4 formed on a buried oxide film 10-3. The film thickness of the buried oxide film 10-3 can be made to be about 5 μm for example. The film thickness of the silicon thin film 10-4 can be made to be about 5 μm for example. The piezo elements 15 can be formed by, for example, diffusing a predetermined impurity such as boron or the like at predetermined regions at the silicon thin film 10-4 of the SOI substrate 10-1. The electrode pads 14 and the wiring pattern can be formed by patterning a conductive film of, for example, aluminum (Al) or the like on the silicon thin film 10-4. Further, as described above, the piezo elements 15 and the electrode pads 14 and the wiring pattern form a Wheatstone bridge circuit.

Next, the SOI substrate 10-1 is disposed such that the surface, on which the piezo elements 15 and the electrode pads 14 and the wiring pattern are formed, is at the bottom side. The surface which is facing upward at this time will be the top surface in the following description. Next, a resist liquid is spin-coated on the top surface of the SOI substrate 10-1, and by carrying out an existing exposure processing and developing processing thereon, a resist pattern R11, which has an opening A11 above the region where the cavity 17 opens, is formed. Next, by etching the SOI substrate 10-1 by using the resist pattern R1 as a mask, as shown in FIG. 4B, the cavity 17 is formed. The etching at this time is stopped at the stage when etching is carried out such that the film thicknesses of the fixed portion 11 and the beam portions 12 and the inner peripheral portion 13b of the weight portion 13 remain. In this way, the fixed portion 11 and the weight portion 13 at the semiconductor acceleration sensor chip 10 are patterned.

Next, after the resist pattern R 1I on the SOI substrate 10-1 is removed, again, a resist liquid is spin-coated on the SOI substrate 10-1, and by carrying out an existing exposure processing and developing processing thereon, a resist pattern R12, which has openings A 12 for forming through-holes in the SOI substrate 10-1, is formed while leaving the beam portions 12 and the fixed portion 11 and the weight portion 13. Next, by etching the SOI substrate 10-1 by using the resist pattern R12 as a mask, holes which pass through the SOI substrate 10-1 are formed. In this way, as shown in FIG. 4C, the beam portions 12 at the semiconductor acceleration sensor chip 10 are patterned, and, as a result, a wafer, in which structures of the semiconductor acceleration sensor chips 10 are arrayed two-dimensionally, is obtained.

Next, by individuating the semiconductor acceleration sensor chips 10 by using, for example, a dicing blade 16, the semiconductor acceleration sensor chip 10 in accordance with the present example (see FIG. 1 and FIG. 2) is manufactured.

<Method of Manufacturing Semiconductor Acceleration Sensor Device 100>

Next, a method of manufacturing the semiconductor acceleration sensor device 100 in accordance with the present example will be described in detail together with the drawings.

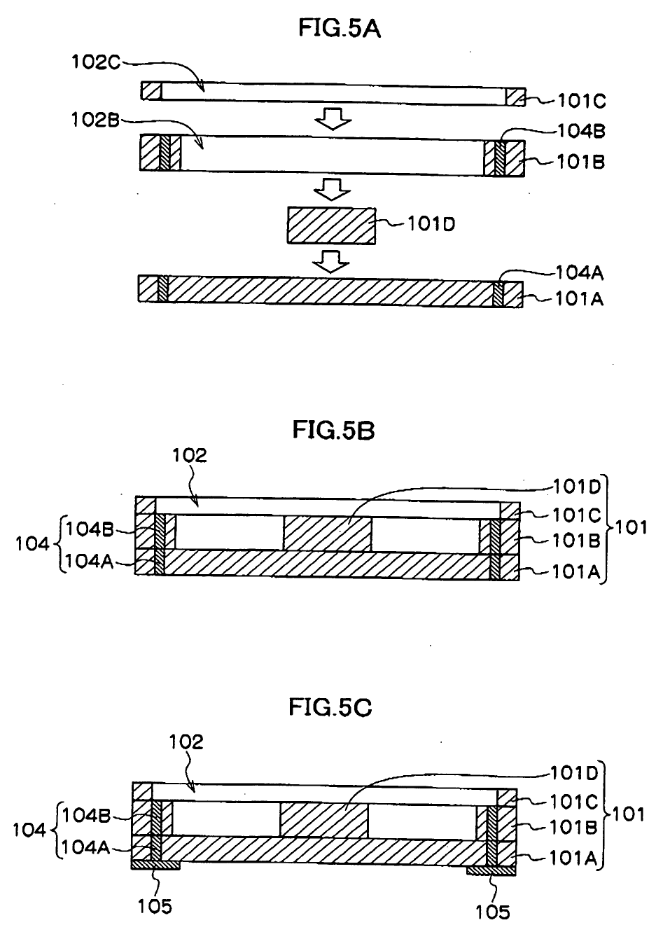

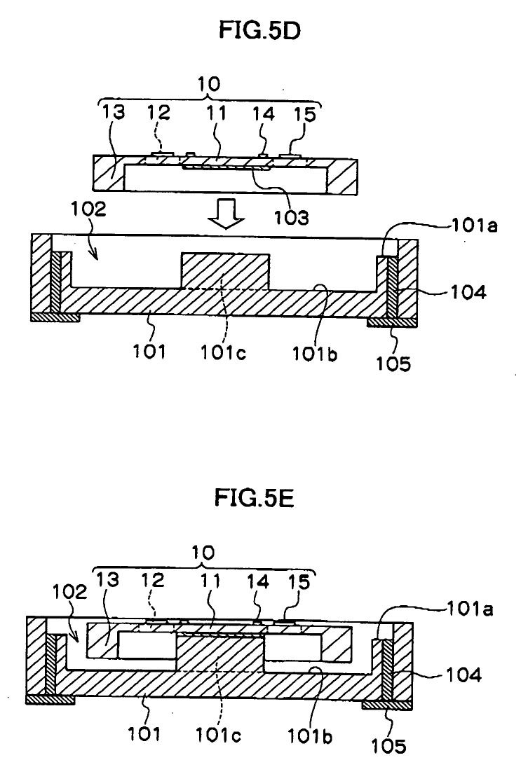

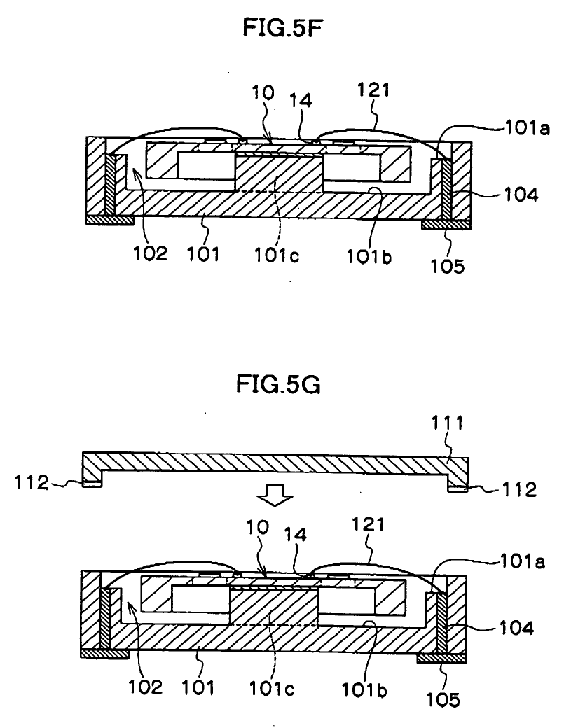

In the present example, first, as shown in FIG. 5A, green sheets 101A, 101B, 101C, and 101D are readied as members for structuring the lower container 101. The green sheet 101D is the member structuring the pedestal portion 101c which projects into the cavity 102. The green sheet 101C is the member structuring the portion which projects-out further than the lower step surface 101a at the side wall of the lower container 101. The green sheet 101B is the member which structures the portion which is further downward than the lower step surface 101a at the side wall of the lower container 101. The green sheet 101A is the member which structures the bottom plate at the lower container 101. Note that each of the green sheets 101C, 101B, and 101A may be a layered sheet formed from a plurality of green sheets being layered.

A cavity hole 102C is punched in the green sheet 101C by using a punching machine. A cavity hole 102B and via holes, which are for forming portions (the upper portions) of the via wires 104, are punched in the green sheet 101B similarly by using a punching machine. Via holes, which are for forming portions (the lower portions) of the via wires 104, are punched in the green sheet 101A similarly by using a punching machine. Note that the cavity hole 102C which is formed in the green sheet 101C is a size larger than the cavity hole 102B formed in the green sheet 101B. In this way, the lower step surface 101a is formed at the time of layering the green sheet 101C and the green sheet 101B. Further, the green sheet 101D is placed on the green sheet 101A so as to be disposed at the substantial center of the cavity hole 102B provided in the green sheet 101B.

Further, the via holes of the green sheet 101B and the via holes of the green sheet 101A are formed at positions which lie one above the other at the time of layering the green sheets 101B and 101A. Conductor patterns 104B and 104A, which become the via wires 104, are formed by a screen printing method for example within these via holes.

Next, as shown in FIG. 5B, the green sheets 101C, 101B, 101D and 101A are layered in order, and after they are pressurized from above and below, firing processing is carried out. The lower container 101, at which the pedestal portion 101c and the cavity 102 and the via wires 104 are formed, is thereby formed. Note that, in this firing processing, the pressure can be made to be normal pressure, the temperature can be made to be 1500° C., and the processing time can be made to be 24 hours.

Thereafter, as shown in FIG. 5C, the foot pattern 105 which is electrically connected to the via wires 104 is formed by a screen printing method for example on the bottom surface of the lower container 101. Note that the foot pattern 105 may be formed before the respective green sheets 101D, 101C, 101B and 101A are joined together.

When the lower container 101, at which the pedestal portion 101c, the via wires 104, and the foot pattern 105 are formed, is readied as described above, next, as shown in FIG. 5D, the resin 103, such as a silicone resin or the like for example, is coated on the bottom surface of the fixed portion 11 at the semiconductor acceleration sensor chip 10. Next, the semiconductor acceleration sensor chip 10 on which the resin 103 is coated is placed on the top surface of the pedestal portion 101c projecting-out from the bottom plate 101b of the lower container 101, and thermal processing is carried out in a state in which they are pressurized from above and below. In this way, as shown in FIG. 5E, the resin 103 hardens, and as a result, the semiconductor acceleration sensor chip 10 is fastened to the pedestal portion 101c. Note that, in this thermal processing, the pressure can be made to be normal pressure, the temperature can be made to be 180° C., and the processing time can be made to be 1 hour.

Next, as shown in FIG. 5F, by bonding the wires 121 which are made of gold for example, the electrode pads 14 at the semiconductor acceleration sensor chip 10 and the via wires 104 formed at the side wall of the lower container 101 are electrically connected. Note that, in the bonding of the wires 121, for example, ultrasonic and thermocompression bonding in which the pressure is made to be 30 gf(/cm²) and the temperature is made to be 230° C. can be used. Further, because the electrode pads 14, to which ones of ends of the wires 121 are bonded, are formed on the fixed portion 11 at the semiconductor acceleration sensor chip 10, the beam portions 12 and the like at the semiconductor acceleration sensor chip 10 do not break at the time of bonding the wires 121.

Next, as shown in FIG. 5G, the upper cover 111 of, for example, 42 Alloy alloy or stainless or the like is readied, and the thermosetting resin 112 such as an epoxy resin or the like is coated on the bottom surface of the upper cover 111. Next, the upper cover 111 is placed on the lower container 101, and by carrying out thermal processing in a state in which they are pressurized from above and below, the upper cover 111 is fastened to the lower container 101. Note that, in this thermal processing, the pressure can be made to be 5 kg(/cm²), the temperature can be made to be 150° C., and the processing time can be made to be 2 hours. In this way, the semiconductor acceleration sensor device 100 such as shown in FIG. 3A and FIG. 3B is manufactured. Note that, at the time of sealing the lower container 101 by the upper cover 111, the interior of the cavity 102 is purged by, for example, nitrogen gas or dry air.

<Operational Effects>

As described above, the semiconductor acceleration sensor chip 10 in accordance with the present example is structured to have the fixed portion 11 having a first thickness, the weight portion 13 surrounding the fixed portion 11 from the periphery, the beam portions 12 which have the first thickness and which connect the fixed portion 11 and the weight portion 13 such that the weight portion 13 can displace with respect to the fixed portion 11, and the piezo elements 15 formed at the beam portions 12.

By making the thickness of the fixed portion 11, which is fastened to the package at the time of accommodating the semiconductor acceleration sensor chip 10 in the package which is formed from the lower container 101 and the upper cover 111, and the thickness of the beam portions 12, be the same first thickness, a process for making the beam portions 12 thinner than the fixed portion 111 becomes unnecessary, and therefore, the manufacturing method can be simplified. Further, by simplifying the manufacturing method, breakage at the time of manufacturing can be prevented. In this way, the yield of the semiconductor acceleration sensor chip 10, and accordingly the semiconductor acceleration sensor device 100, can be improved. Note that, because the beam portions 12 can be made thin to the needed thickness, the sensor sensitivity of the semiconductor acceleration sensor chip 10 is not lowered.

Further, the method of manufacturing the semiconductor acceleration sensor chip 10 in accordance with the present example readies the SOI substrate 10-1 having the electrode pads 14 formed at a predetermined region on the top surface (the region where the fixed portion 11 is formed: this is the first region), the piezo elements 15 formed at a predetermined region which is at the periphery of the first region on the top surface (the region where the beam portions 12 are formed: this is the second region), and the wiring pattern which electrically connects the electrode pads 14 and the piezo elements 15; excavates, from the reverse surface, the first region and the second region and a predetermined region (the region where the weight portion 13 is formed: this is the third region) which is at the periphery of the second region at the SOI substrate 10-1, such that the first thickness remains; and individuates the SOI substrate 10-1 at an end of a fourth region which is at the periphery of the third region.

By making the thickness of the first region, i.e., the thickness of the fixed portion 11, and the thickness of the second region, i.e., the thickness of the beam portions 12, be the same first thickness, a process for making the beam portions 12 thinner than the fixed portion 11 becomes unnecessary, and therefore, the manufacturing method can be simplified. Further, by simplifying the manufacturing method, breakage at the time of manufacturing can be prevented. In this way, the yield of the semiconductor acceleration sensor chip 10 can be improved, and accordingly, the yield of the semiconductor acceleration sensor device 100 can be improved. Note that, because the beam portions 12 can be made thin to the needed thickness, the sensor sensitivity of the semiconductor acceleration sensor chip 10 is not lowered. Moreover, by making the thickness of the third region, which is the inner peripheral portion 13b of the weight portion 13, be the first thickness which is the same as the thickness of the first region which is the fixed portion 11 and the second region which is the beam portions 12, stress at the time when the weight portion 13 displaces with respect to the fixed portion 11 can be prevented from concentrating at the connected portions of the beam portions 12 and the weight portion 13, i.e., at the root portions of the second region and the third region, and, as a result, the shock-resistance of the semiconductor acceleration sensor chip 10 can be improved. Accordingly, the shock-resistance of the semiconductor acceleration sensor device 100 can be improved.

### Example 2

Next, example 2 of the present invention will be described in detail by using the drawings. Note that, in the following explanation, for structures which are similar to example 1, the same reference numerals are given, and detailed description thereof is omitted. Further, structures which are not mentioned specially are similar to example 1.

<Structure of Semiconductor Acceleration Sensor Chip 20>

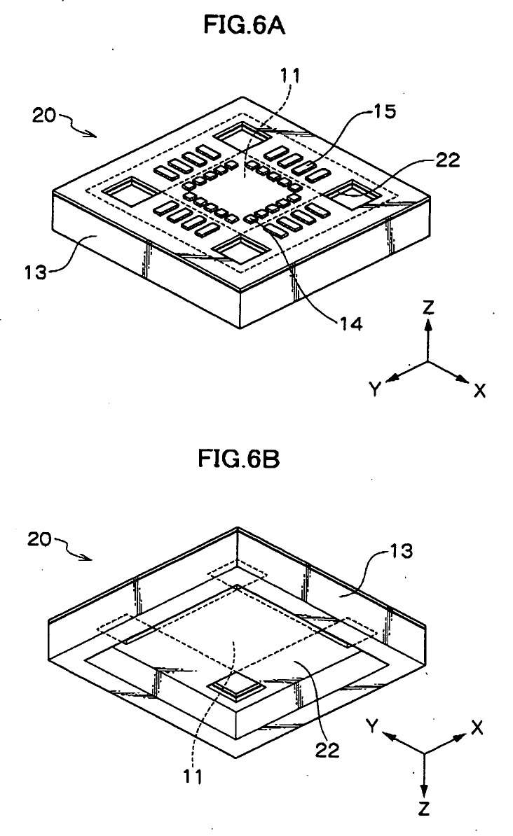

FIG. 6A is a perspective view showing the schematic structure when viewing, obliquely from above, a semiconductor acceleration sensor chip 20, which is a three-dimensional acceleration sensor, in accordance with the present example. FIG. 6B is a perspective view showing the schematic structure when viewing, obliquely from below, the semiconductor acceleration sensor chip 20. Note that, in the present example, in the same way as in example 1, description is given by using, as an example, a three-dimensional acceleration sensor which utilizes the piezoresistance effect, i.e., the phenomenon that the resistance value varies in proportion to the generated stress.

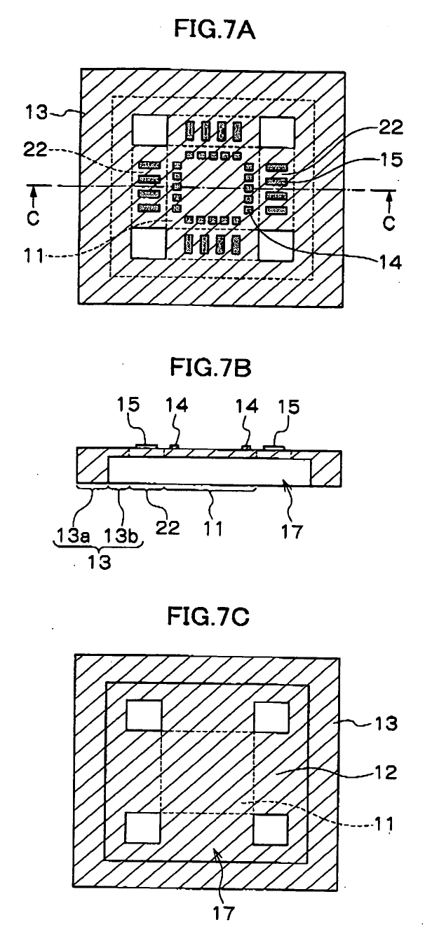

Further, FIG. 7A is a top view of the semiconductor acceleration sensor chip 20, FIG. 7B is a C-C sectional view in FIG. 7A, and FIG. 7C is a bottom view of the semiconductor acceleration sensor chip 20.

As shown in FIG. 6 and FIG. 7, the semiconductor acceleration sensor chip 20 has the fixed portion 11 and the weight portion 13 and the electrode pads 14, in the same way as the semiconductor acceleration sensor chip 10 in example 1. Further, in the semiconductor acceleration sensor chip 20, the beam portions 12 at the semiconductor acceleration sensor chip 10 are replaced with beam portions 22, and a plurality of the piezo elements 15 are provided at each of the beam portions 22. The fixed portion 11 and the beam portions 22 and the weight portion 13 are formed integrally by machining a predetermined semiconductor substrate. Note that a silicon substrate or the like, for example, can be applied as the predetermined semiconductor substrate at which the fixed portion 11 and the beam portions 22 and the weight portion 13 are built-in.

In the same way as in example 1, the semiconductor substrate formed from the fixed portion 11, the beam portions 22, and the weight portion 13 is a quadrilateral-columnar member which has, at the interior thereof, the cavity 17 whose opening configuration is square, and at which the top surface side of the cavity 17 is closed. In other words, the semiconductor substrate which structures the semiconductor acceleration sensor chip 20 has the cavity 17 which is formed by opening from the reverse surface side. Due to this structure, the fixed portion 11 and the beam portions 22 and the inner peripheral portion 13b of the weight portion 13 are made to be thinner-walled than the outer peripheral portion 13a of the weight portion 13.

Here, because the fixed portion 11 and the weight portion 13 are similar to example 1 as described above, an individual, detailed description thereof is omitted.

In the same way as in example 1, four, for example, of the beam portions 22 are provided, and connect the substantial centers of the sides at the inner side of the weight portion 13 and the substantial centers of the sides of the fixed portion 11 respectively (see FIG. 6 and FIG. 7). Each beam portion 22 is formed so as to flex due to the inertial movement of the weight portion 13 when acceleration is applied to the semiconductor acceleration sensor chip 20. Namely, the beam portions 22 are flexible. In this way, the weight portion 13 and the fixed portion 11 are connected by the four beam portions 22 such that the weight portion 13 can displace with respect to the fixed portion 11.

However, the beam portion 22 in accordance with the present example has a width which is equivalent to the length of one side of the fixed portion 11. Accordingly, in the present example, the width of the top surface of the beam portion 22 is about 0.5 mm for example. The other dimensions can be made to be similar to the beam portion 12 in example 1.

Note that the thickness of each beam portion 22 is, in the same way as in example 1, the same as the thickness of the fixed portion 11. In this way, a process for machining the beam portions 22 to be thinner than the fixed portion 11 is not needed, and the manufacturing process is simplified, and breakage at the time of manufacturing is prevented such that the yield improves. Moreover, due to this structure, the stress at the time when the weight portion 13 displaces with respect to the fixed portion 11 can be prevented from concentrating at the connected portions of the beam portions 22 and the fixed portion 11, i.e., at the root portions of the beam portions 22. As a result, the shock-resistance of the semiconductor acceleration sensor chip 20 can be improved.

Further, as described above, a plurality of the piezo elements 15 are formed on the top surface of each of the beam portions 22. A Wheatstone bridge circuit is structured by the plurality of piezo elements 15 being electrically connected by an unillustrated wiring pattern to the electrode pads 14 formed on the top surface of the fixed portion 11.

By providing a plurality of the piezo elements 15 on each of the beam portions 22 in this way, the sensor characteristics can be stabilized. Namely, for example, at each of the beam portions 22, by averaging the resistance values which are taken from the plurality of piezo elements 15, the flexure arising at each beam portion 22 can be stably detected. Further, for example, even in a case in which any one of the piezo elements 15 is broken, because the acceleration can be detected by using the resistance values read-out from the other piezo elements 15, stable sensor operation is possible.

Because the other structures are similar to example 1, detailed description thereof is omitted here.

<Method of Manufacturing Semiconductor Acceleration Sensor Chip 20>

Further, because the method of manufacturing the semiconductor acceleration sensor chip 20 in accordance with the present example is substantially similar to the method of manufacturing the semiconductor acceleration sensor chip 10 in accordance with example 1, detailed description will be omitted here. Note that, in the manufacturing method in accordance with the present example, the resist pattern R12, which is for forming the through-holes in the SOI substrate 10-1 while leaving the beam portions 12 and the fixed portion 11 and the weight portion 13 in the manufacturing method in example 1, is replaced with a resist pattern which is for forming through-holes in the SOI substrate 10-1 while leaving the beam portions 22 and the fixed portion 11 and the weight portion 13. Further, in the manufacturing method in accordance with the present example, a plurality of the piezo elements 15 are formed as shown in FIG. 7A at the region of the SOI substrate 10-1 where the beam portion 22 is formed.

<Structure and Method of Manufacturing Semiconductor Acceleration Sensor Device 200>

Next, the structure of a semiconductor acceleration sensor device 200 in accordance with the present example, which is formed by accommodating the above-described semiconductor acceleration sensor chip 20 in a package formed from the lower container 101 and the upper cover 111, will be described in detail together with the drawings.

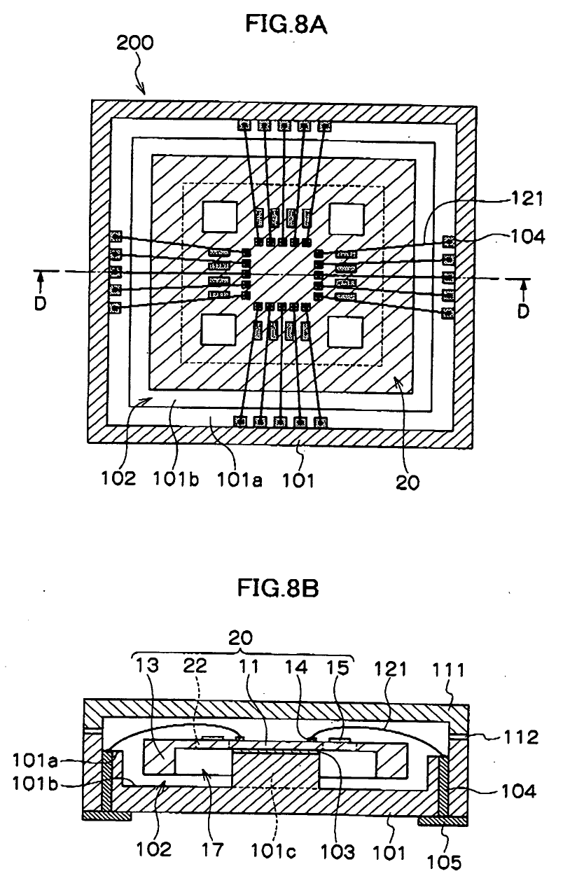

FIG. 8A is a top view showing the structure of the semiconductor acceleration sensor device 200. Further, FIG. 8B is a D-D sectional view in FIG. 8A. Note that, for convenience of explanation, the thermosetting resin 112 and the upper cover 111 at the semiconductor acceleration sensor device 200 are omitted in FIG. 8A.

As shown in FIG. 8A and FIG. 8B, the semiconductor acceleration sensor device 200 can use a package which is similar to example 1. Namely, the semiconductor acceleration sensor device 200 has the lower container 101 which accommodates the semiconductor acceleration sensor chip 20, and the upper cover 111 which seals the lower container 101. Accordingly, due to the present example employing the structure of and the method of manufacturing the package formed from the lower container 101 and the upper cover 111, which were described in example 1, detailed description thereof is omitted.

<Operational Effects>

As described above, the semiconductor acceleration sensor chip 20 in accordance with the present example is structured to have the fixed portion 11 having a first thickness, the weight portion 13 surrounding the fixed portion 11 from the periphery, the beam portions 22 which have the first thickness and which connect the fixed portion 11 and the weight portion 13 such that the weight portion 13 can displace with respect to the fixed portion 11, and the plurality of piezo elements 15 formed at the beam portions 22.

By making the thickness of the fixed portion 11, which is fastened to the package at the time of accommodating the semiconductor acceleration sensor chip 20 in the package which is formed from the lower container 101 and the upper cover 111, and the thickness of the beam portions 22, be the same first thickness, a process for making the beam portions 22 thinner than the fixed portion 11 becomes unnecessary, and therefore, the manufacturing method can be simplified. Further, by simplifying the manufacturing method, breakage at the time of manufacturing can be prevented. In this way, the yield of the semiconductor acceleration sensor chip 20, and accordingly the semiconductor acceleration sensor device 200, can be improved. Note that, because the beam portions 22 can be made thin to the needed thickness, the sensor sensitivity of the semiconductor acceleration sensor chip 20 is not lowered. Further, by providing a plurality of the piezo elements 15 at each of the beam portions 22, the sensor characteristics can be stabilized. Namely, for example, at each of the beam portions 22, by averaging the resistance values which are taken from the plurality of piezo elements 15, the flexure arising at each beam portion 22 can be stably detected. Further, for example, even in a case in which any one of the piezo elements 15 is broken, because the acceleration can be detected by using the resistance values read-out from the other piezo elements 15, stable sensor operation is possible.

Further, the method of manufacturing the semiconductor acceleration sensor chip 20 in accordance with the present example readies the SOI substrate 10-1 having the electrode pads 14 formed at a predetermined region on the top surface (the region where the fixed portion 11 is formed: this is the first region), the piezo elements 15 formed at a predetermined region which is at the periphery of the first region on the top surface (the region where the beam portions 22 are formed: this is the second region), and the wiring pattern which electrically connects the electrode pads 14 and the piezo elements 15; excavates, from the reverse surface, the first region and the second region and a predetermined region (the region where the weight portion 13 is formed: this is the third region) which is at the periphery of the second region at the SOI substrate 10-1, such that the first thickness remains; and individuates the SOI substrate 10-1 at an end of a fourth region which is at the periphery of the third region.

By making the thickness of the first region, i.e., the thickness of the fixed portion 11, and the thickness of the second region, i.e., the thickness of the beam portions 22, be the same first thickness, a process for making the beam portions 22 thinner than the fixed portion 11 becomes unnecessary, and therefore, the manufacturing method can be simplified. Further, by simplifying the manufacturing method, breakage at the time of manufacturing can be prevented. In this way, the yield of the semiconductor acceleration sensor chip 20 can be improved, and accordingly, the yield of the semiconductor acceleration sensor device 200 can be improved. Note that, because the beam portions 22 can be made thin to the needed thickness, the sensor sensitivity of the semiconductor acceleration sensor chip 20 is not lowered. Moreover, by making the thickness of the third region, which is the inner peripheral portion 13b of the weight portion 13, be the first thickness which is the same as the thickness of the first region which is the fixed portion 11 and the second region which is the beam portions 22, stress at the time when the weight portion 13 displaces with respect to the fixed portion 11 can be prevented from concentrating at the connected portions of the beam portions 22 and the weight portion 13, i.e., at the root portions of the second region and the third region, and, as a result, the shock-resistance of the semiconductor acceleration sensor chip 20 can be improved. Accordingly, the shock-resistance of the semiconductor acceleration sensor device 200 can be improved.

Because the other effects are similar to the above-described other example, detailed description thereof is omitted here.

### Example 3

Next, example 3 of the present invention will be described in detail by using the drawings. Note that, in the following explanation, for structures which are similar to example 1 or example 2, the same reference numerals are given, and detailed description thereof is omitted. Further, structures which are not mentioned specially are similar to example 1 or example 2.

<Structure of Semiconductor Acceleration Sensor Chip 30>

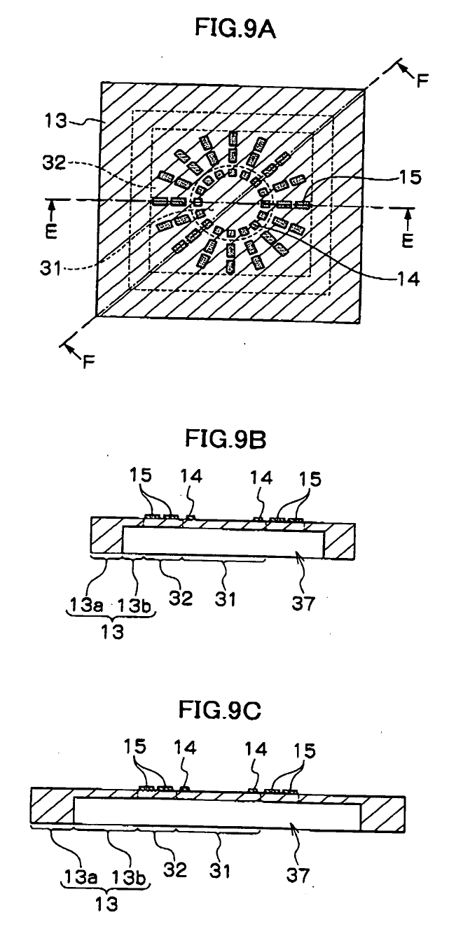

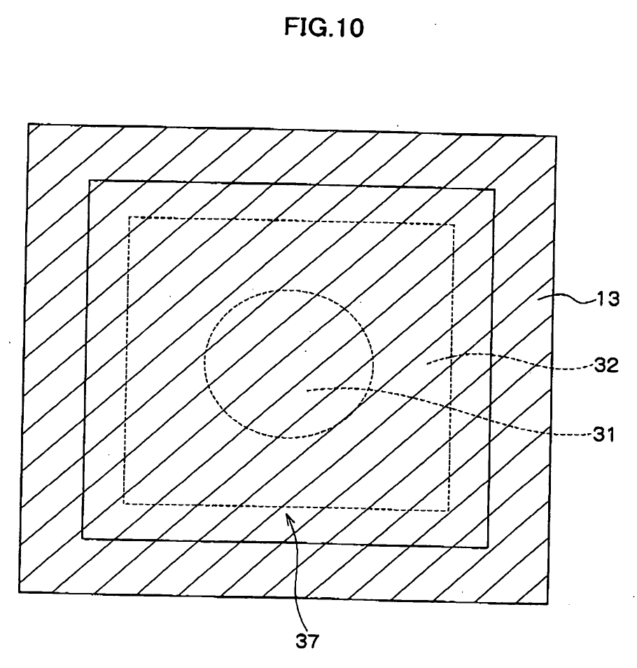

FIG. 9A is a top view of a semiconductor acceleration sensor chip 30, FIG. 9B is an E-E sectional view in FIG. 9A, and FIG. 9C is an F-F sectional view in FIG. 9A. Further, FIG. 10 is a bottom view of the semiconductor acceleration sensor chip 30. Note that, in the present example, in the same way as in examples 1 and 2, description is given by using, as an example, a three-dimensional acceleration sensor which utilizes the piezoresistance effect, i.e., the phenomenon that the resistance value varies in proportion to the generated stress.

As shown in FIG. 9 and FIG. 10, the semiconductor acceleration sensor chip 30 has a fixed portion 31 and a beam portion 32 and the weight portion 13 and the electrode pads 14 and the piezo elements 15. The fixed portion 31 and the beam portion 32 and the weight portion 13 are formed integrally by machining a predetermined semiconductor substrate. Note that, in the same way as in examples 1 and 2, a silicon substrate or the like, for example, can be applied as the predetermined semiconductor substrate at which the fixed portion 31 and the beam portion 32 and the weight portion 13 are built-in.

In the present example, as shown in FIG. 8 and FIG. 9, the central, circular region at the semiconductor substrate which structures the semiconductor acceleration sensor chip 30 is the fixed portion 31. The outer peripheral portion 13a (see FIG. 9B and FIG. 9C), which is the side wall, and an inner peripheral portion 33b (see FIG. 9B and FIG. 9C), which is the region from there to a predetermined distance at the inner side, are the weight portion 13. The region between the fixed portion 31 and the weight portion 13 is the beam portion 32. Note that, in this structure, the weight portion 13 is a configuration similar to examples 1 and 2.

Further, in the same way as in examples 1 and 2, the semiconductor substrate, which is formed from the fixed portion 31, the beam portion 32 and the weight portion 13, is a quadrilateral-columnar member which has, at the interior thereof, the cavity 17 whose opening configuration is square, and at which the top surface side of the cavity 17 is closed. In other words, the semiconductor substrate which structures the semiconductor acceleration sensor chip 30 has the cavity 17 which is formed by opening from the reverse surface side. Due to this structure, the fixed portion 31 and the beam portion 32 and the inner peripheral portion 33b of the weight portion 13 are made to be thinner-walled than the outer peripheral portion 13a of the weight portion 13.

In the above-described structure, the fixed portion 31 is fastened to a pole-shaped pedestal portion 301c provided at the bottom plate 101b of a lower container 301 which will be described later. By making the fixed portion 31, which is disposed at the center of the weight portion 13, be a structure which is fixed to the pole-shaped pedestal portion 301c in this way, the effect which the semiconductor acceleration sensor chip 30 receives when a package, which is formed from the lower container 301 which will be described later and the upper cover 111, deforms, can be reduced in the same way as in examples 1 and 2. Therefore, the need to reinforce the mechanical strength of the semiconductor acceleration sensor chip 30 by using, for example, a glass substrate or the like, is eliminated, and, as a result, the manufacturing process can be simplified.

The beam portion 32 completely closes the region between the fixed portion 31 and the weight portion 13 and connects them. Namely, in the present example, the region from the fixed portion 31 to the weight portion 13 is flush. However, the beam portion 32 in accordance with the present example is formed so as to flex due to the inertial movement of the weight portion 13 when acceleration is applied to the semiconductor acceleration sensor chip 30, in the same way as examples 1 and 2. Namely, the beam portion 32 is flexible.

In the present example, in order to structure the beam portion 32 to flex with respect to the inertial movement of the weight portion 13, the length of the shortest portion of the beam portion 32, i.e., a length which is ½ of the difference between the length of one side of the inner periphery of the weight portion 13 and the diameter of the fixed portion 31, is made to be about 0.3 mm for example, the thickness of the beam portion 32 is made to be about 0.01 mm for example, and the thickness of the thickest portion of the weight portion 13 is made to be about 0.4 mm for example.

Further, in the present example, the thickness of the fixed portion 31 and the thickness of the inner peripheral portion 33b at the weight portion 13 are, similarly to the beam portion 32, made to be about 0.01 mm for example. In this way, a process for machining the beam portion 32 to be thinner than the fixed portion 31 is not needed, and the manufacturing process is simplified, and breakage at the time of manufacturing is prevented such that the yield improves. Moreover, due to this structure, the stress at the time when the weight portion 13 displaces with respect to the fixed portion 31 can be prevented from concentrating at the connected portion of the beam portion 32 and the fixed portion 31, i.e., at the root portion of the beam portion 32. As a result, the shock-resistance of the semiconductor acceleration sensor chip 30 can be improved.

In addition, the diameter of the fixed portion 31 when viewed from above can be made to be about 0.8 mm for example.

Further, a plurality of the piezo elements 15, which are arrayed so as to surround the fixed portion 31 doubly, are formed at the top surface of the beam portion 32. The respective piezo elements 15 are disposed along lines (hereinafter called axes) which extend radially from the center of the fixed portion 31. Further, two of the piezo elements 15 are disposed on each axis. In other words, a plurality of the piezo elements 15, which are arrayed so as to surround the fixed portion 31, and a plurality of the piezo elements 15, which are arrayed so as to further surround these, are formed on the top surface of the beam portion 32.

A Wheatstone bridge circuit is structured by the plurality of piezo elements 15 being electrically connected by an unillustrated wiring pattern to the electrode pads 14 which are formed on the top surface of the fixed portion 31.

By disposing the plurality of piezo elements 15 in this way so as to surround the fixed portion 31, or in other words, in the form of a circle, the flexure arising at the beam portion 32 can be detected more minutely, and, in this way, the acceleration can be detected with higher precision.

<Structure of Semiconductor Acceleration Sensor Device 300>

Next, the structure of a semiconductor acceleration sensor device 300 in accordance with the present example, which is formed by the above-described semiconductor acceleration sensor chip 30 being accommodated in a package formed from the lower container 301 which will be described later and the upper cover 111, will be described in detail together with the drawings.

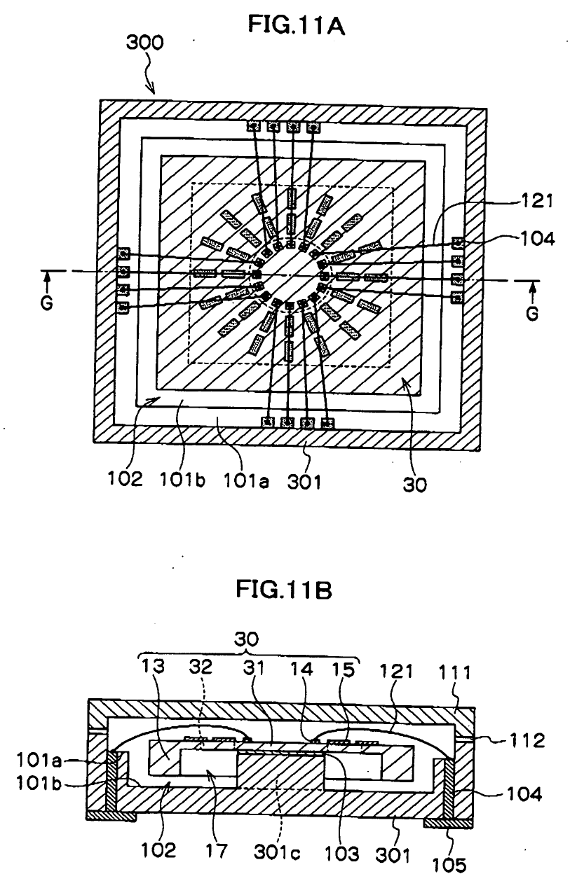

FIG. 11A is a top view showing the structure of the semiconductor acceleration sensor device 300. Further, FIG. 11B is a G-G sectional view in FIG. 1A. Note that, for convenience of explanation, the structures of the thermosetting resin 112 and the upper cover 111 at the semiconductor acceleration sensor device 300 are omitted in FIG. 11A.

As shown in FIG. 11A and FIG. 11B, the semiconductor acceleration sensor device 300 has the lower container 301 which accommodates the semiconductor acceleration sensor chip 30, and the upper cover 111 which seals the lower container 301.

In the same way as the lower container 101 in accordance with examples 1 and 2, the lower container 301 is, for example, a package which is made of ceramic and has a layered structure. The lower container 301 has the cavity 102 for accommodating the semiconductor acceleration sensor chip 30.

The cavity 102 is, in the same way as examples 1 and 2, a size larger than the outer dimension of the semiconductor acceleration sensor chip 30. Accordingly, the semiconductor acceleration sensor chip 30 is accommodated within the cavity 102 such that the weight portion 13 is in a midair state.

In the same way as examples 1 and 2, the side wall of the lower container 301, which forms the side surface of the cavity 102, has at the inner side thereof, i.e., the cavity 102 side thereof, the lower step surface 101a which is a step lower than the top surface at the outer side. The upper ends of the via wires 104, which are formed so as to pass through the interior of the side wall to the bottom surface of the lower container 301, are exposed at the lower step surface 101a. Other ends of the wires 121, whose one ends are attached to the electrode pads 14 of the semiconductor acceleration sensor chip 30, are attached to these exposed portions. Further, the lower ends of the via wires 104 exposed at the bottom surface of the lower container 301 are electrically connected to electrode pads (these are called the foot pattern 105) formed on the bottom surface of the lower container 301. In this way, the electrode pads 14 of the semiconductor acceleration sensor chip 30 are electrically lead-out to the foot pattern 105 of the bottom surface of the lower container 301, via the wires 121 and the via wires 104.

The pole-shaped pedestal portion 301c, which projects-out into the cavity 102, is provided at the bottom plate 101b of the lower container 301. The configuration of the pedestal portion 301c when viewed from above is, for example, a circle which is a size smaller than the fixed portion 31. However, the pedestal portion 301c is not limited to the same, and may be modified in any way provided that it is of a size and a configuration which does not protrude-out from the fixed portion 31 of the semiconductor acceleration sensor chip 30 when viewed from above, and is of an extent that it can fasten the fixed portion 31 with sufficient strength. As described above, the bottom surface of the fixed portion 31 of the semiconductor acceleration sensor chip 30 is fastened to the top surface of the pedestal portion 301c. Accordingly, the upper portion of the pedestal portion 301c is accommodated in the cavity 17 of the semiconductor acceleration sensor chip 30. For the fastening of the fixed portion 31 and the pedestal portion 301c, the resin 103 of a polyorganosiloxane or the like having a siloxane bond (Si—O) as the skeleton, such as a silicone resin or the like for example, can be used. Further, other than this, for example, a fluorine resin or the like can be applied.

As described above, ones of ends of the wires 121 are attached to the via wires 104 which are exposed at the lower step surface 101a of the side wall of the lower container 301. Further, also as described above, the other ends of the wires 121 are attached to the electrode pads 14 of the semiconductor acceleration sensor chip 30. Metal wires of, for example, gold or copper or aluminum or the like, can be used as these wires 121. Further, the wires 121 can be bonded to the via wires 104 and the electrode pads 14 by using, for example, ultrasonic and thermocompression bonding or the like.

Moreover, the open side of the lower container 301, at which the semiconductor acceleration sensor chip 30 is accommodated within the cavity 102 as described above, is sealed by the upper cover 111. For example, 42 Alloy alloy or stainless or the like can be used as the material of the upper cover 111. The thermosetting resin 112, such as an epoxy resin or the like, can be used in the adhering of the lower container 301 and the upper cover 111: Note that the interior of the package formed from the lower container 301 and the upper cover 111 is purged by, for example, nitrogen gas or dry air or the like.

Because the other structures are similar to example 1 or 2, detailed description thereof is omitted here.

<Method of Manufacturing Semiconductor Acceleration Sensor Chip 30>

In the method of manufacturing the semiconductor acceleration sensor chip 30 in accordance with the present example, formation is possible by omitting the process described by using FIG. 4C in the method of manufacturing the semiconductor acceleration sensor chip 10 in accordance with example 1. Namely, formation is possible by omitting the process of forming holes which pass-through the S01 substrate 10-1 and patterning the beam portions 12. Therefore, detailed description is omitted in the present example. Note that, in the manufacturing method in accordance with the present example, a plurality of the piezo elements 15 are formed as shown in FIG. 8A at the region of the SOI substrate 10-1 where the beam portion 32 is formed.

<Method of Manufacturing Semiconductor Acceleration Sensor Device 300>

Next, a method of manufacturing the semiconductor acceleration sensor device 300 in accordance with the present example is described in detail together with the drawings. Note that, in the method of manufacturing the semiconductor acceleration sensor device 300 in accordance with the present example, the process of accommodating the semiconductor acceleration sensor chip 30 in the package formed from the lower container 301 and the upper cover 111 is substantially the same as example 1 or 2, and therefore, detailed description thereof is omitted here. Accordingly, hereinafter, only the method of manufacturing the lower container 301 is described.

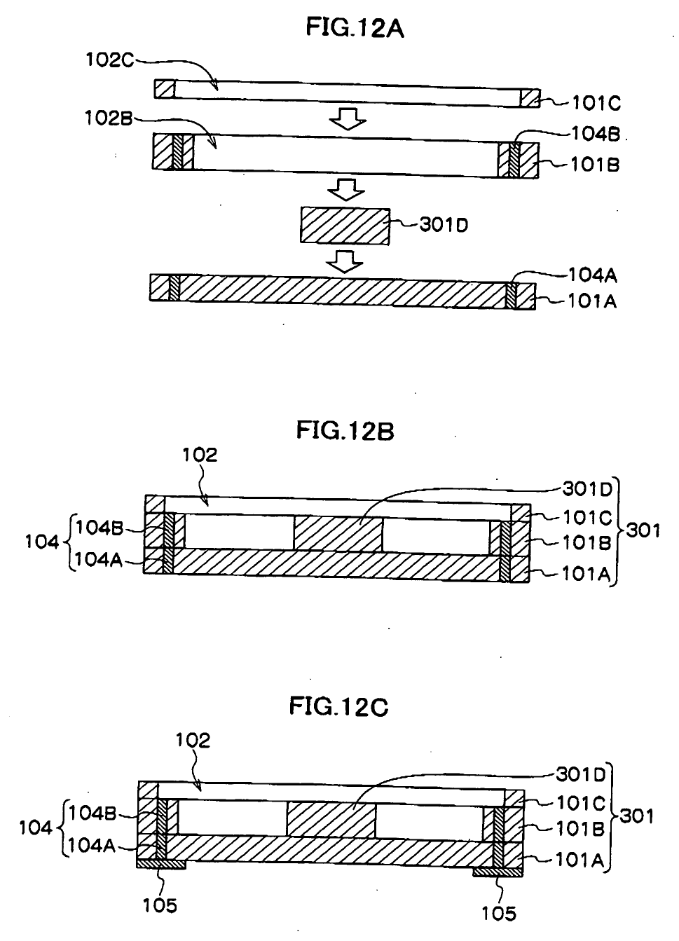

In the present example, first, as shown in FIG. 12A, the green sheets 101A, 101B, 101C, and 301D are readied as members for structuring the lower container 301. The green sheet 301D is the member structuring the pedestal portion 301c which projects into the cavity 102. The green sheet 101C is the member structuring the portion which projects-out further than the lower step surface 101a at the side wall of the lower container 301. The green sheet 101B is the member which structures the portion which is further downward than the lower step surface 101a at the side wall of the lower container 301. The green sheet 101A is the member which structures the bottom plate at the lower container 301. Note that each of the green sheets 101C, 101B, and 101A may be a layered sheet formed from a plurality of green sheets being layered.

Similarly to example 1, the cavity hole 102C is punched in the green sheet 101C by using a punching machine. The cavity hole 102B and via holes, which are for forming portions (the upper portions) of the via wires 104, are punched in the green sheet 101B similarly by using a punching machine. Via holes, which are for forming portions (the lower portions) of the via wires 104, are punched in the green sheet 101A similarly by using a punching machine, in the same way as in example 1. Note that the cavity hole 102C which is formed in the green sheet 101C is a size larger than the cavity hole 102B formed in the green sheet 101B. In this way, the lower step surface 101a is formed at the time of layering the green sheet 101C and the green sheet 101B. Further, the green sheet 301D is placed on the green sheet 101A so as to be disposed at the substantial center of the cavity hole 102B provided in the green sheet 101B.

Further, the via holes of the green sheet 101B and the via holes of the green sheet 101A are formed at positions which lie one above the other at the time of layering the green sheets 101B and 101A. The conductor patterns 104B and 104A, which become the via wires 104, are formed by a screen printing method for example within these via holes.

Next, as shown in FIG. 12B, the green sheets 101C, 101B, 301D and 101A are layered in order, and after they are pressurized from above and below, firing processing is carried out. The lower container 301, at which the pedestal portion 301c and the cavity 102 and the via wires 104 are formed, is thereby formed. Note that, in this firing processing, the pressure can be made to be normal pressure, the temperature can be made to be 1500° C., and the processing time can be made to be 24 hours.

Thereafter, as shown in FIG. 12C, the foot pattern 105 which is electrically connected to the via wires 104 is formed by a screen printing method for example on the bottom surface of the lower container 301. Note that the foot pattern 105 may be formed before the respective green sheets 301D, 101C, 101B and 101A are joined together.

The lower container 301 in accordance with the present example is formed through the above-described processes. Thereafter, as described in example 1 by using FIG. 4 and FIG. 5D, FIG. 5E, the fixed portion 31 of the semiconductor acceleration sensor chip 30 is fastened to the pedestal portion 301c of the lower container 301 by using the resin 103, such as a silicone resin or the like for example. Next, by bonding the wires 121 which are made of gold for example, the electrode pads 14 at the semiconductor acceleration sensor chip 30 and the via wires 104 formed at the side wall of the lower container 301 are electrically connected. Thereafter, by fastening the upper cover 111, which is 42 Alloy alloy or stainless or the like, to the opening of the lower container 301 by using the thermosetting resin 112 such as an epoxy resin or the like for example, this is sealed. In this way, the semiconductor acceleration sensor device 300 such as shown in FIG. 11A and FIG. 11B is manufactured. Note that, at the time of sealing the lower container 301 by the upper cover 111, the interior of the cavity 102 is purged by, for example, nitrogen gas or dry air.

<Operational Effects>

As described above, the semiconductor acceleration sensor chip 30 in accordance with the present example is structured to have the fixed portion 31 having a first thickness, the weight portion 13 surrounding the fixed portion 31 from the periphery, the beam portion 32 which has the first thickness and which connects the fixed portion 31 and the weight portion 13 such that the weight portion 13 can displace with respect to the fixed portion 31, and the plurality of piezo elements 15 formed at the beam portion 32 so as to surround the fixed portion 31.

By making the thickness of the fixed portion 31, which is fastened to the package at the time of accommodating the semiconductor acceleration sensor chip 30 in the package which is formed from the lower container 301 and the upper cover 111, and the thickness of the beam portion 32, be the same first thickness, a process for making the beam portion 32 thinner than the fixed portion 31 becomes unnecessary, and therefore, the manufacturing method can be simplified. Further, by simplifying the manufacturing method, breakage at the time of manufacturing can be prevented. In this way, the yield of the semiconductor acceleration sensor chip 30, and accordingly the semiconductor acceleration sensor device 300, can be improved. Note that, because the beam portion 32 can be made thin to the needed thickness, the sensor sensitivity of the semiconductor acceleration sensor chip 30 is not lowered. Further, by disposing the plurality of piezo elements 15 so as to surround the fixed portion 31, or in other words, in the form of a circle, the flexure arising at the beam portion 32 can be detected more minutely, and, in this way, the acceleration can be detected with higher precision.

Further, the method of manufacturing the semiconductor acceleration sensor chip 30 in accordance with the present example readies the SOI substrate 10-1 having the electrode pads 14 formed at a predetermined region on the top surface (the region where the fixed portion 31 is formed: this is the first region), the piezo elements 15 formed at a predetermined region which is at the periphery of the first region on the top surface (the region where the beam portion 32 is formed: this is the second region), and the wiring pattern which electrically connects the electrode pads 14 and the piezo elements 15; excavates, from the reverse surface, the first region and the second region and a predetermined region (the region where the weight portion 13 is formed: this is the third region) which is at the periphery of the second region at the SOI substrate 10-1, such that the first thickness remains; and individuates the SOI substrate 10-1 at an end of a fourth region which is at the periphery of the third region.

By making the thickness of the first region, i.e., the thickness of the fixed portion 31, and the thickness of the second region, i.e., the thickness of the beam portion 32, be the same first thickness, a process for making the beam portion 32 thinner than the fixed portion 31 becomes unnecessary, and therefore, the manufacturing method can be simplified. Further, by simplifying the manufacturing method, breakage at the time of manufacturing can be prevented. In this way, the yield of the semiconductor acceleration sensor chip 30 can be improved, and accordingly, the yield of the semiconductor acceleration sensor device 300 can be improved. Note that, because the beam portion 32 can be made thin to the needed thickness, the sensor sensitivity of the semiconductor acceleration sensor chip 30 is not lowered. Moreover, by making the thickness of the third region, which is the inner peripheral portion 13b of the weight portion 13, be the first thickness which is the same as the thickness of the first region which is the fixed portion 31 and the second region which is the beam portion 32, stress at the time when the weight portion 13 displaces with respect to the fixed portion 31 can be prevented from concentrating at the connected portion of the beam portion 32 and the weight portion 13, i.e., at the root portion of the second region and the third region, and, as a result, the shock-resistance of the semiconductor acceleration sensor chip 30 can be improved. Accordingly, the shock-resistance of the semiconductor acceleration sensor device 300 can be improved.

Because the other effects are similar to the above-described other examples, detailed description thereof is omitted here.

### Example 4

Next, example 4 of the present invention will be described in detail by using the drawings. Note that, in the following explanation, for structures which are similar to any of example 1 through example 3, the same reference numerals are given, and detailed description thereof is omitted. Further, structures which are not mentioned specially are similar to any of example 1 through example 3.

<Structure of Semiconductor Acceleration Sensor Chip 40>

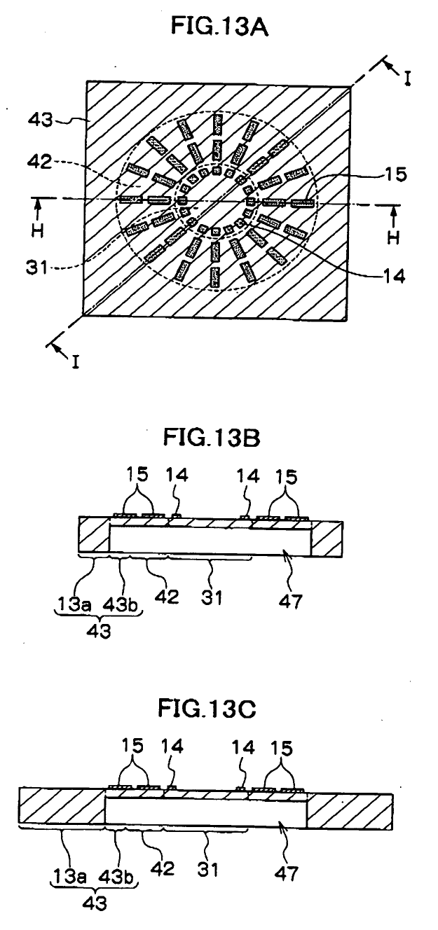

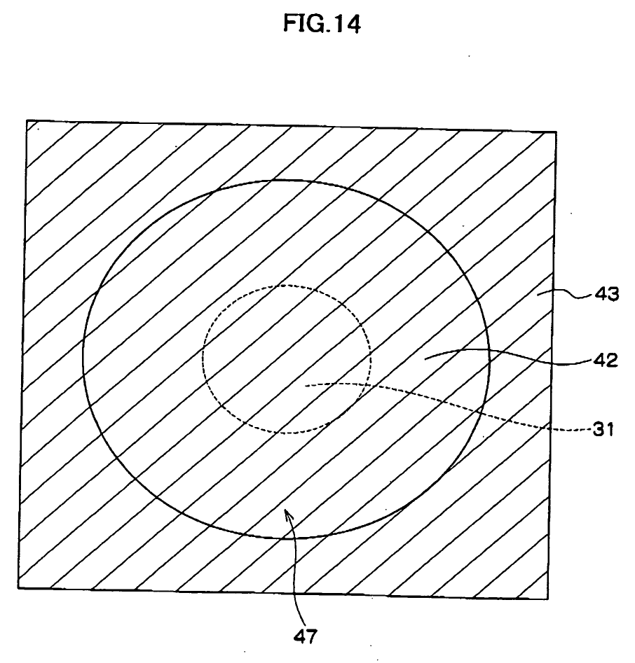

FIG. 13A is a top view of a semiconductor acceleration sensor chip 40, FIG. 13B is an H-H sectional view in FIG. 13A, and FIG. 13C is an I-I sectional view in FIG. 13A. Further, FIG. 14 is a bottom view of the semiconductor acceleration sensor chip 40. Note that, in the present example, in the same way as in examples 1 through 3, description is given by using, as an example, a three-dimensional acceleration sensor which utilizes the piezoresistance effect, i.e., the phenomenon that the resistance value varies in proportion to the generated stress.

As shown in FIG. 13 and FIG. 14, the semiconductor acceleration sensor chip 40 has the fixed portion 31 and a beam portion 42 and a weight portion 43 and the electrode pads 14 and the piezo elements 15. The fixed portion 31 and the beam portion 42 and the weight portion 43 are formed integrally by machining a predetermined semiconductor substrate. Note that, in the same way as in examples 1 through 3, a silicon substrate or the like, for example, can be applied as the predetermined semiconductor substrate at which the fixed portion 31 and the beam portion 42 and the weight portion 43 are built-in.

In the present example, as shown in FIG. 12 and FIG. 13, the central, circular region at the semiconductor substrate which structures the semiconductor acceleration sensor chip 40 is the fixed portion 31. The outer peripheral portion 13a (see FIG. 13B and FIG. 13C), which is the side wall, and an inner peripheral portion 43b (see FIG. 13B and FIG. 13C), which is the region from there to a predetermined distance at the inner side, are the weight portion 43. The region between the fixed portion 31 and the weight portion 43 is the beam portion 42. Note that, in this structure, the fixed portion 31 is a configuration similar to example 3.

Further, in the same way as in examples 1 through 3, the semiconductor substrate, which is formed from the fixed portion 31, the beam portion 42 and the weight portion 43, is a quadrilateral-columnar member which has, at the interior thereof, a cavity 47 whose opening configuration is circular, and at which the top surface side of the cavity 47 is closed. In other words, the semiconductor substrate which structures the semiconductor acceleration sensor chip 40 has the cavity 47 which is formed by opening from the reverse surface side. Due to this structure, the fixed portion 31 and the beam portion 42 and the inner peripheral portion 43b of the weight portion 43 are made to be thinner-walled than the outer peripheral portion 13a of the weight portion 43. However, the opening configuration of the cavity 47 in accordance with the present example is circular. The volume at the semiconductor acceleration sensor chip 40 which the thick portion at the weight portion 43, i.e., an outer peripheral portion 43a, occupies, is greater when the opening configuration is circular than when the opening configuration is square, in a case in which, for example, the length of one side of the square and the diameter of the circle are the same length. Namely, by making the opening configuration circular, the weight portion 43 can be made to be heavier. In this way, the amount by which the beam portion 43 flexes due to the acceleration arising at the semiconductor acceleration sensor chip 40 can be made to be large, and the sensor sensitivity of a semiconductor acceleration sensor device 400 can be increased. By making the opening configuration circular, the size of the outer peripheral portion 43a can be made to be small, and therefore, the semiconductor acceleration sensor chip 40 can be made to be compact.

In the above-described structure, in the same way as in example 3, the fixed portion 31 is fastened to the pole-shaped pedestal portion 301c provided at the bottom plate 101b of the lower container 301. By making the fixed portion 31, which is disposed at the center of the weight portion 43, be a structure which is fixed to the pole-shaped pedestal portion 301c in this way, the effect which the semiconductor acceleration sensor chip 40 receives when the package, which is formed from the lower container 301 and the upper cover 111, deforms, can be reduced in the same way as in examples 1 through 3. Therefore, the need to reinforce the mechanical strength of the semiconductor acceleration sensor chip 40 by using, for example, a glass substrate or the like, is eliminated, and, as a result, the manufacturing process can be simplified.

In the same way as in example 3, the beam portion 42 completely closes the region between the fixed portion 31 and the weight portion 43 and connects them. Namely, in the present example, the region from the fixed portion 31 to the weight portion 43 is flush. However, the beam portion 42 in accordance with the present example is formed so as to flex due to the inertial movement of the weight portion 43 when acceleration is applied to the semiconductor acceleration sensor chip 40, in the same way as examples 1 through 3. Namely, the beam portion 42 is flexible.

In the present example, in order to structure the beam portion 42 to flex with respect to the inertial movement of the weight portion 43, the length of the shortest portion of the beam portion 42, i.e., a length which is ½ of the difference between the diameter of the weight portion 43 and the diameter of the fixed portion 31, is made to be about 0.3 mm for example, the thickness of the beam portion 42 is made to be about 0.01 mm for example, and the thickness of the thickest portion of the weight portion 43 is made to be about 0.4 mm for example.

Further, in the present example, the thickness of the fixed portion 31 and the thickness of the inner peripheral portion 43b at the weight portion 43 are, similarly to the beam portion 42, made to be about 0.01 mm for example. In this way, a process for machining the beam portion 42 to be thinner than the fixed portion 31 is not needed, and the manufacturing process is simplified, and breakage at the time of manufacturing is prevented such that the yield improves. Moreover, due to this structure, the stress at the time when the weight portion 43 displaces with respect to the fixed portion 31 can be prevented from concentrating at the connected portion of the beam portion 42 and the fixed portion 31, i.e., at the root portion of the beam portion 42. As a result, the shock-resistance of the semiconductor acceleration sensor chip 40 can be improved.

In addition, the diameter of the fixed portion 31 when viewed from above can be made to be about 0.8 mm for example.

Further, in the same way as in example 3, a plurality of the piezo elements 15, which are arrayed so as to surround the fixed portion 31 doubly, are formed at the top surface of the beam portion 42. The respective piezo elements 15 are disposed along lines (hereinafter called axes) which extend radially from the center of the fixed portion 31. Further, two of the piezo elements 15 are disposed on each axis. In other words, a plurality of the piezo elements 15, which are arrayed so as to surround the fixed portion 31, and a plurality of the piezo elements 15, which are arrayed so as to further surround these, are formed on the top surface of the beam portion 42. By disposing the plurality of piezo elements 15 in this way so as to surround the fixed portion 31, or in other words, in the form of a circle, the flexure arising at the beam portion 42 can be detected more minutely by using the Wheatstone bridge circuit which the piezo elements 15 structure, and, in this way, the acceleration can be detected with higher precision.

<Method of Manufacturing Semiconductor Acceleration Sensor Chip 30>

Further, in the method of manufacturing the semiconductor acceleration sensor chip 40 in accordance with the present example, in the same way as the semiconductor acceleration sensor chip 30 in accordance with example 3, formation is possible by omitting the process described by using FIG. 4C in the method of manufacturing the semiconductor acceleration sensor chip 10 in accordance with example 1, and therefore, detailed description thereof is omitted here. Note that, in the manufacturing method in accordance with the present example, a plurality of the piezo elements 15 are formed as shown in FIG. 12A at the region at the SOI substrate 10-1 where the beam portion 42 is formed, in the same way as example 3. Further, in the manufacturing method in accordance with the present example, the resist pattern R11 for forming the cavity 17 is replaced with a resist pattern for forming the cavity 47. Namely, the resist pattern used in the process shown in FIG. 4B is replaced with a resist pattern having a circular opening.

<Structure and Method of Manufacturing Semiconductor Acceleration Sensor Device 400>

Next, the structure of the semiconductor acceleration sensor device 400 in accordance with the present example, which is formed by accommodating the above-described semiconductor acceleration sensor chip 40 in a package formed from the lower container 301 and the upper cover 111, will be described in detail together with the drawings.

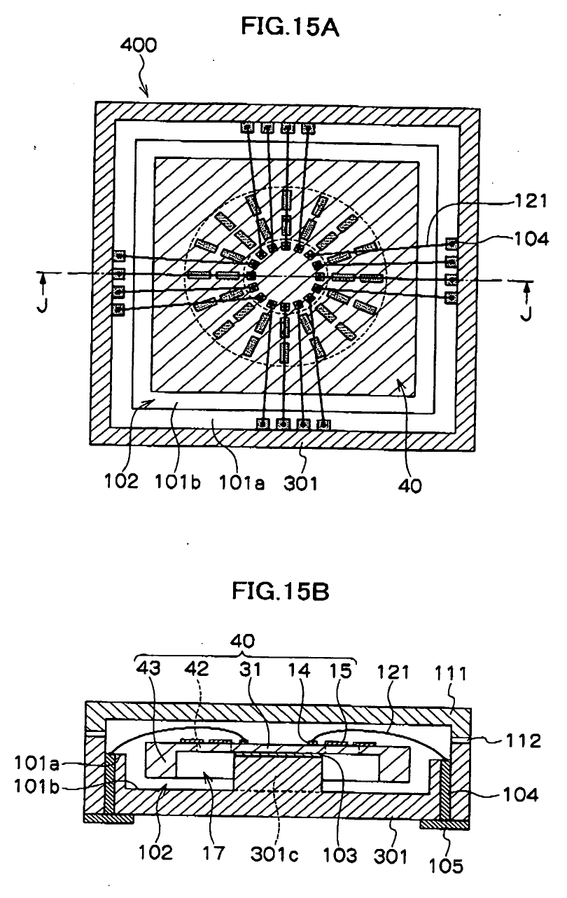

FIG. 15A is a top view showing the structure of the semiconductor acceleration sensor device 400. Further, FIG. 15B is a J-J sectional view in FIG. 15A. Note that, for convenience of explanation, the structures of the thermosetting resin 112 and the upper cover 111 at the semiconductor acceleration sensor device 400 are omitted in FIG. 15A.

As shown in FIG. 15A and FIG. 15B, the semiconductor acceleration sensor device 400 can use a package which is similar to example 3. Namely, the semiconductor acceleration sensor device 400 has the lower container 301 which accommodates the semiconductor acceleration sensor chip 40, and the upper cover 111 which seals the lower container 301. Accordingly, due to the present example employing the structure of and the method of manufacturing the package formed from the lower container 301 and the upper cover 111, which were described in examples 1 and 3, detailed description thereof is omitted.

<Operational Effects>

As described above, the semiconductor acceleration sensor chip 40 in accordance with the present example is structured to have the fixed portion 31 having a first thickness, the weight portion 43 which surrounds the fixed portion 31 from the periphery and which has a second thickness which is thicker than the first thickness and whose configuration at the border with a first thickness portion is circular, the beam portion 42 which has the first thickness and which connects the fixed portion 31 and the weight portion 43 such that the weight portion 43 can displace with respect to the fixed portion 31, and the plurality of piezo elements 15 formed at the beam portion 42 so as to surround the fixed portion 31.

By making the thickness of the fixed portion 31, which is fastened to the package at the time of accommodating the semiconductor acceleration sensor chip 40 in the package which is formed from the lower container 301 and the upper cover 111, and the thickness of the beam portion 42, be the same first thickness, a process for making the beam portion 42 thinner than the fixed portion 31 becomes unnecessary, and therefore, the manufacturing method can be simplified. Further, by simplifying the manufacturing method, breakage at the time of manufacturing can be prevented. In this way, the yield of the semiconductor acceleration sensor chip 40, and accordingly the semiconductor acceleration sensor device 400, can be improved. Note that, because the beam portion 42 can be made thin to the needed thickness, the sensor sensitivity of the semiconductor acceleration sensor chip 40 is not lowered. Further, by disposing the plurality of piezo elements 15 so as to surround the fixed portion 31, or in other words, in the form of a circle, the flexure arising at the beam portion 42 can be detected more minutely, and, in this way, the acceleration can be detected with higher precision. Still further, by making the configuration of the border between the first thickness portion and the second thickness portion be circular, the volume which the thick portion of the weight portion 43, i.e., the outer peripheral portion 43a, occupies at the semiconductor acceleration sensor chip 40 can be made to be larger than a case in which the configuration of this border is square. Namely, by making the configuration of the border circular, the weight portion 43 can be made to be heavier. In this way, the amount by which the beam portion 43 flexes due to the acceleration arising at the semiconductor acceleration sensor chip 40 can be made to be large, and the sensor sensitivity of the semiconductor acceleration sensor device 400 can be increased. Yet further, by making the configuration of the border circular, the size of the outer peripheral portion 43a can be made to be small, and therefore, the semiconductor acceleration sensor chip 40 can be made to be compact.

Further, the method of manufacturing the semiconductor acceleration sensor chip 40 in accordance with the present example readies the SOI substrate 10-1 having the electrode pads 14 formed at a predetermined region on the top surface (the region where the fixed portion 31 is formed: this is the first region), the piezo elements 15 formed at a predetermined region which is at the periphery of the first region on the top surface (the region where the beam portion 42 is formed: this is the second region), and the wiring pattern which electrically connects the electrode pads 14 and the piezo elements 15; excavates, from the reverse surface, the first region and the second region and a predetermined region (the region where the weight portion 43 is formed: this is the third region) which is at the periphery of the second region at the SOI substrate 10-1, such that the first thickness remains; and individuates the SOI substrate 10-1 at an end of a fourth region which is at the periphery of the third region.

By making the thickness of the first region, i.e., the thickness of the fixed portion 31, and the thickness of the second region, i.e., the thickness of the beam portion 42, be the same first thickness, a process for making the beam portion 42 thinner than the fixed portion 31 becomes unnecessary, and therefore, the manufacturing method can be simplified. Further, by simplifying the manufacturing method, breakage at the time of manufacturing can be prevented. In this way, the yield of the semiconductor acceleration sensor chip 40 can be improved, and accordingly, the yield of the semiconductor acceleration sensor device 400 can be improved. Note that, because the beam portion 42 can be made thin to the needed thickness, the sensor sensitivity of the semiconductor acceleration sensor chip 40 is not lowered. Moreover, by making the thickness of the third region, which is the inner peripheral portion 43b of the weight portion 43, be the first thickness which is the same as the thickness of the first region which is the fixed portion 31 and the second region which is the beam portion 42, stress at the time when the weight portion 43 displaces with respect to the fixed portion 31 can be prevented from concentrating at the connected portion of the beam portion 42 and the weight portion 43, i.e., at the root portion of the second region and the third region, and, as a result, the shock-resistance of the semiconductor acceleration sensor chip 40 can be improved. Accordingly, the shock-resistance of the semiconductor acceleration sensor device 400 can be improved.

Because the other effects are similar to the above-described other examples, detailed description thereof is omitted here.

### Example 5

Next, example 5 of the present invention will be described in detail by using the drawings. Note that, in the following explanation, for structures which are similar to any of example 1 through example 4, the same reference numerals are given, and detailed description thereof is omitted. Further, structures which are not mentioned specially are similar to any of example 1 through example 4.

<Structure and Method of Manufacture of Semiconductor Acceleration Sensor Chip>

In the present example, any of the semiconductor acceleration sensor chips 10 through 40 exemplified in examples 1 through 4 can be employed as the semiconductor acceleration sensor chip applied to a semiconductor acceleration sensor device 500. In the following description, a case using the semiconductor acceleration sensor chip 20 in accordance with example 2 is given as an example. Accordingly, because the structure and the method of manufacturing the semiconductor acceleration sensor chip in accordance with the present example were described in example 2, detailed description thereof is omitted here.

<Structure of Semiconductor Acceleration Sensor Device 500>

Next, the structure of the semiconductor acceleration sensor device 500 in accordance with the present example, which is formed by accommodating the above-described semiconductor acceleration sensor chip 20 in a package formed from a lower container 501 which will be described later and the upper cover 111, will be described in detail together with the drawings.

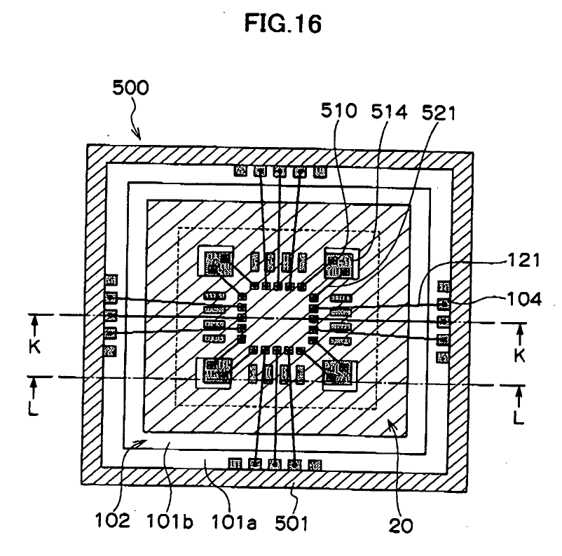

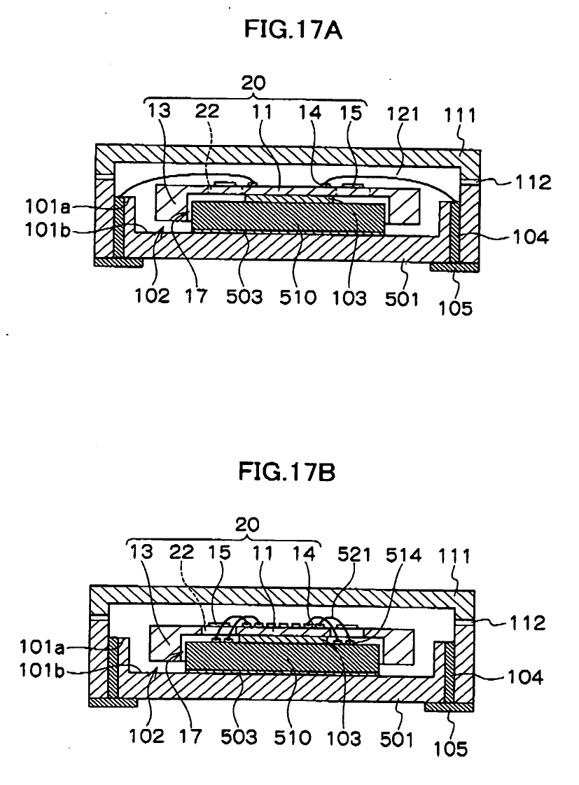

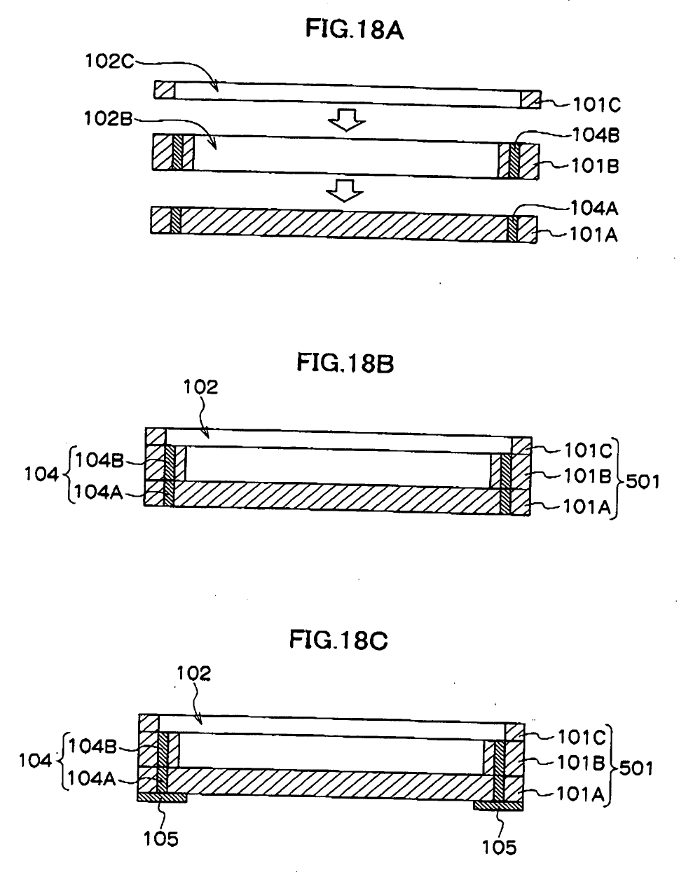

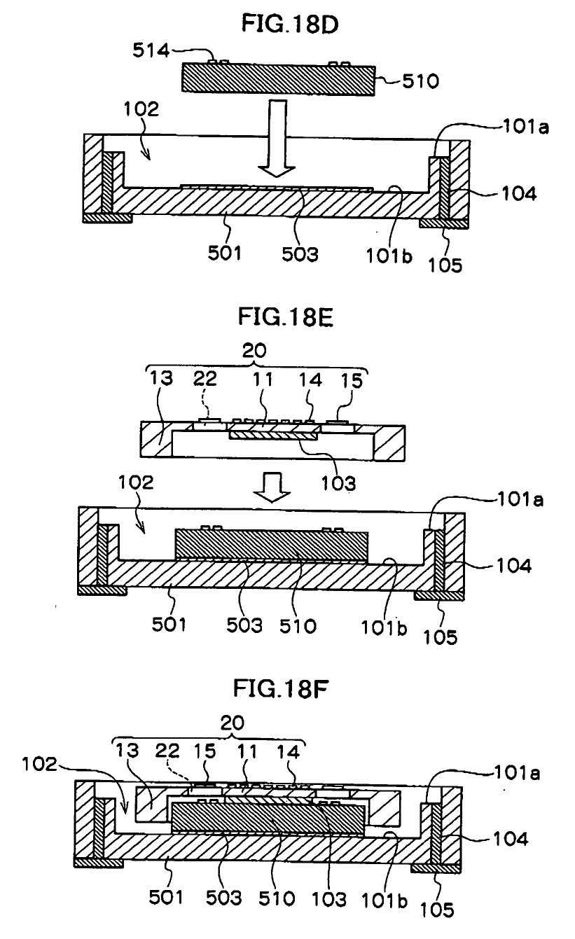

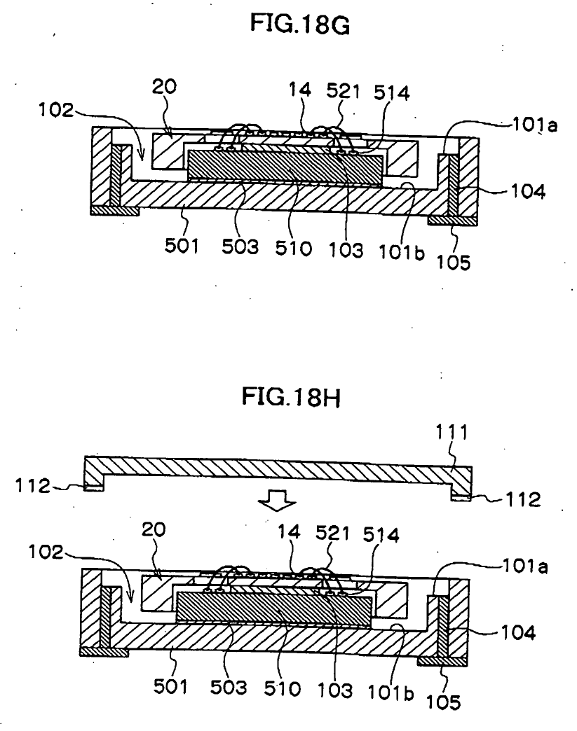

FIG. 16 is a top view showing the structure of the semiconductor acceleration sensor device 500. Further, FIG. 17A is a K-K sectional view in FIG. 16, and FIG. 17B is an L-L sectional view in FIG. 16. Note that, for convenience of explanation, the structures of the thermosetting resin 112 and the upper cover 111 in the semiconductor acceleration sensor device 500 are omitted in FIG. 18.

As shown in FIG. 15 and FIG. 16, the semiconductor acceleration sensor device 500 has the lower container 501 which accommodates the semiconductor acceleration sensor chip 20, and the upper cover 111 which seals the lower container 501.

The lower container 501 has a structure in which the pedestal portion 101c or 301c is eliminated from a structure similar to the lower containers 101 and 301 in accordance with examples 1 through 4. Note that, because the other structures are similar to the lower containers 101 and 301, detailed description thereof is omitted here.

At the lower container 501, a control circuit (also called a control IC) 510 is fixed to the substantial center of the bottom surface of the cavity 102 by using a resin 503 such as a silicone resin or the like for example. This control circuit 510 has electrode pads 514 which are electrically connected to the electrode pads 14 of the semiconductor acceleration sensor chip 20 by wires 521. Note that, in the case of the present example, the wires 521 can be passed through the through-holes which are formed for patterning the beam portions 22 at the semiconductor acceleration sensor chip 20. Therefore, the wires connecting the semiconductor acceleration sensor chip 20 and the control circuit 510 can be made to be short, and the sensor characteristics of the semiconductor acceleration sensor device 500 can be improved.

Further, the control circuit 510, which is fixed to the center of the bottom surface of the cavity 102 of the lower container 501 as described above, exhibits the same function as the pedestal portions 101c, 301c in the above-described respective examples. Namely, the control circuit 510 functions also as a pedestal portion for fastening the semiconductor acceleration sensor chip 20 within the cavity 102 such that the weight portion 13 is in a midair state. In this way, the need for providing a control circuit at the exterior of the package formed form the lower container 501 and the upper cover 111 is eliminated, and the size of the semiconductor acceleration sensor device overall, including the peripheral circuits, can be reduced. Further, in the present example, because the physical distance between the control circuit 510 and the semiconductor acceleration sensor chip 20 becomes short, the lengths of the wires connecting the semiconductor acceleration sensor chip 20 and the control circuit 510 can be made to be short, and, as a result, the sensor characteristics of the semiconductor acceleration sensor device 500 can be improved.

Note that, because the other structures are similar to above-described examples 1 through 4, detailed description thereof is omitted here.

<Method of Manufacturing Semiconductor Acceleration Sensor Device 500>

Next, a method of manufacturing the semiconductor acceleration sensor device 500 in accordance with the present example will be described in detail together with the drawings.

In the present example, first, as shown in FIG. 18A, the green sheets 101A, 101B, and 101C are readied as members for structuring the lower container 501. Namely, the green sheet 101D for forming the pedestal portion 101c in the method of manufacturing the lower container 101 described in example 1 is eliminated.

Next, as shown in FIG. 18B, the green sheets 101C, 101B, and 101A are layered in order, and after they are pressurized from above and below, firing processing is carried out. The lower container 501, at which the pedestal portion 101c and the cavity 102 and the via wires 104 are formed, is thereby formed. Note that, in this firing processing, the pressure can be made to be normal pressure, the temperature can be made to be 1500° C., and the processing time can be made to be 24 hours.

Thereafter, as shown in FIG. 18C, the foot pattern 105 which is electrically connected to the via wires 104 is formed by a screen printing method for example on the bottom surface of the lower container 501. Note that the foot pattern 105 may be formed before the respective green sheets 101C, 101B and 101A are joined together.

When the lower container 501 at which the via wires 104 and the foot pattern 105 are formed is readied as described above, next, in FIG. 18D, the resin 103, such as a silicone resin or the like for example, is coated at the center of the top surface of the bottom plate 101b of the lower container 501, i.e., the center of the bottom surface of the cavity 102. Next, the control circuit 510 is placed on the resin 503.

Next, as shown in FIG. 18E, the resin 103, such as a silicone resin or the like for example, is coated on the bottom surface of the fixed portion 11 at the semiconductor acceleration sensor chip 20. Next, the semiconductor acceleration sensor chip 20 on which the resin 103 is coated is placed on the top surface of the control circuit 510 projecting-out from the bottom plate 101b of the lower container 501, and thermal processing is carried out in a state in which they are pressurized from above and below. In this way, as shown in FIG. 18F, the resins 503 and 103 harden, and as a result, the control circuit 510 is fastened to the center of the bottom surface of the cavity 102, and the semiconductor acceleration sensor chip 20 is fastened to the top surface of the control circuit 510. Note that, in this thermal processing, the pressure can be made to be normal pressure, the temperature can be made to be 180° C., and the processing time can be made to be 1 hour.

Next, as shown in FIG. 18C, by bonding the wires 521 which are made of gold for example and the wires 121 (not illustrated), the electrode pads 14 at the semiconductor acceleration sensor chip 20 and the electrode pads 514 at the control circuit 510, and the electrode pads 14 (not shown) at the semiconductor acceleration sensor chip 20 and the via wires 104 formed in the side wall of the lower container 501, are respectively electrically connected. Note that, in the bonding of the wires 521 and 121, for example, ultrasonic and thermocompression bonding in which the pressure is made to be 30 gf(/cm²) and the temperature is made to be 230° C. can be used. Further, because the electrode pads 14, to which ones of ends of the wires 521 and 121 are bonded, are formed on the fixed portion 11 at the semiconductor acceleration sensor chip 20, the beam portions 22 and the like at the semiconductor acceleration sensor chip 20 do not break at the time of bonding the wires 521 and 121.

Next, as shown in FIG. 18C, the upper cover 111 of, for example, 42 Alloy alloy or stainless or the like is readied, and the thermosetting resin 112 such as an epoxy resin or the like is coated on the bottom surface of the upper cover 111. Next, the upper cover 111 is placed on the lower container 501, and by carrying out thermal processing in a state in which they are pressurized from above and below, the upper cover 111 is fastened to the lower container 501. Note that, in this thermal processing, the pressure can be made to be 5 kg(/cm²), the temperature can be made to be 150° C., and the processing time can be made to be 2 hours. In this way, the semiconductor acceleration sensor device 500 such as shown in FIG. 16 and FIG. 17 is manufactured. Note that, at the time of sealing the lower container 501 by the upper cover 111, the interior of the cavity 102 is purged by, for example, nitrogen gas or dry air.

<Operational Effects>

As described above, the semiconductor acceleration sensor device 500 in accordance with the present example has the package formed from the upper cover 111 and the lower container 501 having the cavity 102 which accommodates the fixed portion (e.g., 11) and the beam portion (e.g., 12) and the weight portion (e.g., 13), and the control circuit 510 which has the electrode pads 514 electrically connected to the piezo elements 15 and whose bottom surface is fastened to the center of the bottom surface of the cavity 102, and has a structure in which the fixed portion (e.g., 11) is fastened to the top surface of the control circuit 510.

In this way, the control circuit 510 which is fastened to the bottom surface of the cavity 102 exhibits the same function as the pedestal portions 101c, 301c in the above-described respective examples. Namely, the control circuit 510 functions also as a pedestal portion for fastening the semiconductor acceleration sensor chip (e.g., 20) within the cavity 102 such that the weight portion 13 is in a midair state. In this way, the need for providing a control circuit at the exterior of the package formed from the lower container 501 and the upper cover 111 is eliminated, and the size of the semiconductor acceleration sensor device overall, including the peripheral circuits, can be reduced. Further, in the present example, because the physical distance between the control circuit 510 and the semiconductor acceleration sensor chip 20 becomes short, the lengths of the wires connecting the semiconductor acceleration sensor chip 20 and the control circuit 510 can be made to be short, and, as a result, the sensor characteristics of the semiconductor acceleration sensor device 500 can be improved.

By making the thickness of the fixed portion (e.g., 11), which is fastened to the package at the time of accommodating the semiconductor acceleration sensor chip (e.g., 20) in the package which is formed from the lower container (e.g., 101) and the upper cover 111, and the thickness of the beam portions (e.g., 22), be the same first thickness, a process for making the beam portions (e.g., 22) thinner than the fixed portion (e.g., 11) becomes unnecessary, and therefore, the manufacturing method can be simplified. Further, by simplifying the manufacturing method, breakage at the time of manufacturing can be prevented. In this way, the yield of the semiconductor acceleration sensor chip 20, and accordingly the semiconductor acceleration sensor device 200, can be improved. Note that, because the beam portion 22 can be made thin to the needed thickness, the sensor sensitivity of the semiconductor acceleration sensor chip 20 is not lowered. Further, by providing a plurality of the piezo elements 15 at each of the beam portions 22, the sensor characteristics can be stabilized. Namely, for example, at each of the beam portions 22, by averaging the resistance values which are taken from the plurality of piezo elements 15, the flexure arising at each beam portion 22 can be stably detected. Further, for example, even in a case in which any one of the piezo elements 15 is broken, because the acceleration can be detected by using the resistance values read-out from the other piezo elements 15, stable sensor operation is possible.

Because the other effects are similar to the above-described other examples, detailed description thereof is omitted here.

Further, above-described example 1 through example 5 are merely examples for implementing the present invention, and the present invention is not limited to these, and modifying these examples variously is within the scope of the present invention, and further, it is obvious from the above description that various other examples are possible within the scope of the present invention.

What is claimed is:

1. A semiconductor acceleration sensor comprising:
a fixed portion having a first thickness;
a weight portion surrounding the fixed portion from a periphery;
a beam portion having the first thickness, and connecting the fixed portion and the weight portion such that the weight portion can displace with respect to the fixed portion; and
a piezo element formed at the beam portion.

2. The semiconductor acceleration sensor of claim 1, wherein the weight portion includes an inner peripheral portion, which has the first thickness and is directly connected to the beam portion, and an outer peripheral portion, which has a second thickness thicker than the first thickness and which is formed around the inner peripheral portion.

3. The semiconductor acceleration sensor of claim 1, wherein
at least two of the beam portions connect the fixed portion and the weight portion, and
a plurality of the piezo elements are formed at each of the beam portions.

4. The semiconductor acceleration sensor of claim 1, wherein
the beam portion is formed at an entirety between the fixed portion and the weight portion, and
a plurality of the piezo elements are formed along a circle whose center is the fixed portion.

5. The semiconductor acceleration sensor of claim 1, wherein a boundary between the outer peripheral portion and the inner peripheral portion is circular.

6. The semiconductor acceleration sensor of claim 1, wherein a plurality of the piezo elements are formed along an axis passing through a center of the fixed portion.

7. The semiconductor acceleration sensor of claim 1, further comprising:
a first electrode pad formed at the fixed portion; and
a wiring pattern electrically connecting the first electrode pad and the piezo element.

8. The semiconductor acceleration sensor of claim 1, further comprising:
a package having a cavity which accommodates the fixed portion and the beam portion and the weight portion, and a pedestal portion which projects-out from a predetermined surface of the cavity,
wherein the fixed portion is fastened to a top surface of the pedestal portion.

9. The semiconductor acceleration sensor of claim 1, further comprising:
a package having a cavity which accommodates the fixed portion and the beam portion and the weight portion; and
a control circuit having a second electrode pad electrically connected to the piezo element, a bottom surface of the control circuit being fastened to a center of a predetermined surface of the cavity,
wherein the fixed portion is fastened to a top surface of the control circuit.

10. The semiconductor acceleration sensor of claim 3, further comprising:
a first electrode pad formed at the fixed portion;
a wiring pattern electrically connecting the first electrode pad and the piezo elements;
a package having a cavity which accommodates the fixed portion and the beam portions and the weight portion;
a control circuit having a second electrode pad, a bottom surface of the control circuit being fastened to a center of a predetermined surface of the cavity; and
a wire passing through between the fixed portion and the weight portion and between the beam portions which are adjacent, and electrically connecting the first electrode pad and the second electrode pad,
wherein the fixed portion is fastened to a top surface of the control circuit.

11. A method of manufacturing a semiconductor acceleration sensor, comprising:
a step of readying a semiconductor acceleration substrate having a first electrode pad formed at a first region at a top surface, a piezo element formed at a second region which is at a periphery of the first region at the top surface, and a wiring pattern electrically connecting the first electrode pad and the piezo element;
a step of excavating, from a reverse surface, the first region and the second region at the semiconductor substrate, such that a first thickness remains; and
a step of individuating the semiconductor substrate at an end of a third region which surrounds the second region.

12. A method of manufacturing a semiconductor acceleration sensor, comprising:
a step of readying a semiconductor acceleration substrate having a first electrode pad formed at a first region at a top surface, a piezo element formed at a second region which is at a periphery of the first region at the top surface, and a wiring pattern electrically connecting the first electrode pad and the piezo element;
a step of excavating, from a reverse surface, the first region and the second region and a third region which is at a periphery of the second region at the semiconductor substrate, such that a first thickness remains; and
a step of individuating the semiconductor substrate at an end of a fourth region which is at a periphery of the third region.

13. The method of manufacturing a semiconductor acceleration sensor of claim 11, wherein the semiconductor substrate is excavated from the reverse surface such that an opening configuration is circular.

14. The method of manufacturing a semiconductor acceleration sensor of claim 11, further comprising a step of forming at least two beam portions which connect the first region and the third region, by forming through-holes in at least two regions at the second region.

15. The method of manufacturing a semiconductor acceleration sensor of claim 14, wherein the through-holes are formed at positions where a plurality of the piezo elements are provided at each of the beam portions.

16. The method of manufacturing a semiconductor acceleration sensor of claim 11, wherein a plurality of the piezo elements are formed along a circle whose center is the first region.

17. The method of manufacturing a semiconductor acceleration sensor of claim 11, further comprising:
a step of readying a package having a cavity, and a pedestal portion projecting-out from a predetermined surface of the cavity; and
a step of fastening the first region, at the semiconductor substrate which has been individuated, to a top surface of the pedestal portion.

18. The method of manufacturing a semiconductor acceleration sensor of claim 11, further comprising:
a step of readying a package having a cavity;
a step of readying a control circuit which is electrically connected to the semiconductor substrate and which has a predetermined thickness;
a step of fastening a bottom surface of the control circuit to a predetermined surface of the cavity; and
a step of fastening the first region, at the semiconductor substrate which has been individuated, to a top surface of the control circuit.
